(19) United States
(12) Patent Application Publication
(10) Pub. No.: US 2002/0056922 A1
(43) Pub. Date: May 16, 2002

(54) Semiconductor device, production method thereof, and coil spring cutting jig and coil spring guiding jig applied thereto

(75) Inventors: Takuo Funaya, Tokyo (JP); Naoji Senba, Tokyo (JP); Nobuaki Takahashi, Tokyo (JP); Sakae Kitajyo, Tokyo (JP); Yuzo Shimada, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/014,074

(22) Filed: Nov. 13, 2001

(30) Foreign Application Priority Data
Nov. 15, 2000 (JP) 348272

(51) Int. Cl. H01L 23/48; H01L 21/44

(52) U.S. Cl. 257/778; 257/688; 438/117

(57) ABSTRACT

A metal layer is formed on each surface of topside substrate electrodes on a substrate. Another metal layer is formed on each surface of chip electrodes on a function element chip. Both ends of vertical coil springs are connected to the topside substrate electrodes and the chip electrodes through the metal layers, respectively. In this way, the topside substrate electrodes are connected to the chip electrodes through the vertical coil springs by means of flip hip bonding. Thereby, there is provided a semiconductor device having flip chip bonding structure, a production method thereof, a coil spring cutting jig and a coil spring guiding jig applied thereto, wherein: it is possible to prevent faulty connection caused by the thermal expansion difference between a function element device and a substrate; after a function element device and a substrate that are connected through a connection formation is separated from each other because a faulty point has been found in an electrical inspection after the tentative connection, it is possible to easily reconnect the function element device and the substrate; the configuration is simple and the packaging cost is low; and even if a high-power-consumption-type function element device is applied, it is possible to realize low thermal resistibility and high reliability of connection.

### BACKGROUND OF THE INVENTION

The present invention relates to a semiconductor device comprising flip chip bonding structure in order to improve reliability of connection, production method thereof, coil spring cutting jig and coil spring guiding jig applied thereto.

### DESCRIPTION OF THE RELATED ART

In a conventional semiconductor device having flip chip bonding structure, there is an important task to prevent stress concentration on a connecting bump caused by the thermal expansion difference of materials used in packaging.

In Japanese Patent Application Laid-Open No. HEI9-321170, there is disclosed a semiconductor device comprising a substrate and a function element device (semiconductor element) sealed with sealant onto the substrate. In this semiconductor device, an elastic heat transmission material is provided between the substrate and a mother board that mounts the substrate in order to securely connect the substrate to the mother board even if the shape of the substrate is warped by the thermal expansion difference between the sealant and the substrate.

However, in this technique, it is troublesome that the reliability of connection between the function element device and the substrate is not improved.

Besides, another semiconductor device disclosed in Japanese Patent Application Laid-Open No. HEI5-160198 forms complex structure so as to prevent stress concentration. FIG. 1 is a cross sectional view showing a configuration of the semiconductor device. As shown in FIG. 1, in the semiconductor device, an organic multilayer interconnection substrate 62 is adhered on a mounting substrate 63. Wirings 57 are made on the undersurface of the mounting substrate 63. Besides, electrodes 61 are formed on the top surface of the organic multilayer interconnection substrate 62. Further, an elastic interconnection substrate 55 having electrodes 54 on the both sides thereof is made above the organic multilayer interconnection substrate 62. Moreover, bumps 60 are disposed between the electrodes 54 formed on the undersurface of the elastic interconnection substrate 55 and the electrodes 61 formed on the top surface of the organic multilayer interconnection substrate 62. The electrodes 54 are connected to the electrodes 61 through the bumps 60. Concerned with the elastic interconnection substrate 55, the electrodes 54 formed on the top surface of the elastic interconnection substrate 55 and those formed on the undersurface thereof are placed in zigzags one another.

Further, a function element device 51 having electrodes 52 on the undersurface thereof is made above the elastic interconnection substrate 55. Besides, bumps 53 are disposed between the electrodes 54 formed on the top surface of the elastic interconnection substrate 55 and the electrodes 52. The electrodes 54 are connected to the electrodes 52 through the bumps 53. In addition, a cap 64 having cavity structure doubling as a cooling wheel (ventilated rib) is adhered on the top surface of the function element device 51 through an insulative elastic material 56. Besides, the cap 64 is adhered to the mounting board 63 through an adhesive line 65. The cap 64 covers the organic multilayer interconnection substrate 62, elastic interconnection substrate 55 and function element device 51. The cap 64 and the mounting board 63 form a cavity 66.

By this configuration, the semiconductor device prevents stress concentration on the bumps 53 and the bumps 60 that connect the function element device 51 placed between the mounting board 63 and the cap 64 to the mounting board 63 electrically and mechanically. This configuration is formed with a view to absorbing the thermal expansion difference between the cap 64 and the mounting board 63 by the insulative elastic material 56, bumps 53, elastic interconnection substrate 55, bumps 60, organic multilayer interconnection substrate 62 and adhesive line 65.

However, in this semiconductor device, the structure for absorbing stress concentration on the bumps is extremely complex. Accordingly, there are some problems: the parts structure thereof becomes more complex; the manufacturing process thereof also becomes more complex and multiprocess; and packaging cost becomes high. Besides, when a package of a high power consumption function element device with a heatsink is applied, it is impossible to connect the function element device 51 directly to the heatsink (cap 64) by metal. Thereby, heat transmission resistance gets high.

Besides, according to a conventional flip chip bonding by a C4 (Controlled Collapse Chip Connection) technique and so forth, first, metal bumps having solder, gold etc. are formed on connecting pads on a function element device (semiconductor element). After that, heat and load are applied thereto in the case of metal-joint between the metal bumps and corresponding connecting electrodes on a substrate. Accordingly, concerned with the conventional semiconductor device having the flip chip bonding structure by the C4 technique etc., the metal bumps are connected to both of the connecting pads on the function element device and the connecting electrodes on the substrate by means of solid phase diffusion welding. Thereby, when an electrical inspection (cable check) is executed after the function element device is connected to the substrate, and a faulty point is found at the connecting area of the function element device, or that between the function element device and the substrate, the connecting body between the function element device and the substrate is reheated. Then, after the metal bumps are molten or they come into an active state, the function element device is peeled off from the substrate. This reheating and peeling cause damages to the function element device and each of the electrodes of the substrate. Besides, it becomes difficult to reconnect the peeled function element device to the substrate because it is hard to keep the shape of the peeled bumps. In the case of reconnecting the peeled function element device to the substrate, it is needed to eliminate the bumps and clean the electrodes. However, even if these processes are executed, there is still a problem that the reliability between the function element device and the substrate after the reconnection deteriorates. This problem is unsolved by the above-described technique.

In Japanese Patent Application Laid-Open No. HEI7-161865, there is disclosed a technique with a view to avoiding the above-described damages arising from reconnecting the function element device and the substrate. First, a function element device (semiconductor element) is fixed to a flame. Then, the function element device and the flame are mounted on a package body. After that, a plurality of pin holes are made in the package body. Then, inductive pin terminals and helical compression springs are placed in the pin holes. The helical coil springs are placed between the pin terminals and the package body and spring-load the pin terminals to have the pin terminals stick out from the package body. By this action of the helical compression springs, the pin terminals are pressed to connecting electrodes formed on the substrate. Thereby, it is possible to connect the contact pins to the connecting electrodes without solder.

However, this technique has the following problems. Concerned with the technique disclosed in the Japanese Patent Application Laid-Open No. HEI7-161865, there is a problem that the configuration of the semiconductor device becomes more complex as well as that disclosed in the Japanese Patent Application Laid-Open No. HEI5-160198. Thereby, the manufacturing cost of the semiconductor device gets high. Besides, it becomes difficult to miniaturize the semiconductor device. Further, it is impossible to effectively prevent a faulty connection caused by the thermal expansion difference between the function element device and the flame and that between the function element device and the package body.

### SUMMARY OF THE INVENTION

It is therefore an object of the present invention to provide a semiconductor device having flip chip bonding structure, production method thereof, coil spring cutting jig and coil spring guiding jig applied thereto, wherein: it is possible to prevent a faulty connection, which is caused by the thermal expansion difference between a function element device and a substrate; after once separating a function element device from a substrate, which are regarded as defective at an electrical inspection after a provisional connection, it is easy to reconnect them; the configuration is simple and the packaging cost is low; it is possible to realize low thermal resistibility even in the case of using a high-power-consumption-type function element device; and reliability of connection is high.

According to a first aspect of the present invention, for achieving the object mentioned above, there is provided a semiconductor device comprising:

a function element device including a plurality of connection pads;

a substrate including a plurality of connecting electrodes, to which the function element device is connected by means of clip chip bonding; and

a plurality of coil springs set between the connecting pads and the connecting electrodes, and connecting the connecting pads and the connecting electrodes.

In the present invention, the coil spring is applied to a connection between the function element device and the substrate as a substitute for the conventional bump. Thereby, it is possible to absorb stress concentration caused by the thermal expansion difference between the function element device and the substrate by expansion and contraction of the coil springs. Therefore, there is obtained a semiconductor device having flip chip bonding structure wherein the configuration is simple and the packaging cost is low. Besides, there is no need to take account of the thermal expansion difference. Therefore, it is possible to directly join a heatsink to the function element device. Further, in the case of using high-power-consumption-type function element device, it is possible to realize low thermal resistibility. Besides, bumps such as solder are not used in this invention. Therefore, when a faulty point is found in the function element device or in a connection area between the function element device and the substrate by an electrical inspection executed after connecting the function element device to the substrate, it is possible to peel the function element device from the substrate without heating. Thereby, it becomes easier to reconnect the peeled function element device and the substrate. Therefore, there is obtained a semiconductor device having flip chip bonding structure wherein reliability of connection is high even after the reconnection.

According to a second aspect of the present invention, it is possible to set the axial of at least one coil spring in a direction substantially vertical to a face opposed to the function element device. Thereby, it is possible to effectively relieve stress especially acting in a direction substantially vertical to the face opposed to the function element device. Besides, it is possible to set the axial of at least one coil spring in a direction substantially horizontal to a face opposed to the function element device. Thereby, it is possible to effectively relax stress especially acting in a direction substantially horizontal to the face opposed to the function element device. Therewith, a connection is realized wherein generation of electric noise is reduced. Further, a large number of contact points are made between the connection pads and the coil springs, and between the substrate and the coil springs. Thereby, it is possible to further enhance reliability of connection.

Incidentally, the coil springs may be applied to a connection between the function element devices, between the substrates, between the motherboards, and between the substrate and the mother board.

According to a third aspect of the present invention, there is provided a production method of a semiconductor device, in a wafer on which a plurality of function element devices having connecting pads are set, comprising steps of:

connecting a plurality of coil springs, which are set on each of the connecting pads arranged in a line so that each axial of the coil springs substantially runs in a direction parallel to the arranging direction of the connecting pads, to the connecting pads;

embrocating resist on the wafer, exposing and developing the wafer, forming openings between the connecting pads, and revealing parts of the coil springs in between the connecting pads;

eliminating the revealed parts of the coil springs by etching;

eliminating the resist;

cutting the wafer into each of the function element devices; and

connecting the cut function element devices to a plurality of connecting electrodes of a substrate through the coil springs.

In the present invention, after the coil springs joined by each other are connected to the plurality of connecting pads on the surface of the wafer, the coil springs are cut into a prescribed length corresponding to each of the connecting pads. Thereby, it is possible to connect the coil springs that are hard to handle because of their imperceptibility to the function element devices easily and effectively.

According to a fourth aspect of the present invention, there is provided a production method of a semiconductor device, in a substrate having connecting electrodes, comprising steps of:

connecting a plurality of coil springs, which are set on each of the connecting electrodes arranged in a line so that each axial of the coil springs substantially runs in a direction parallel to the arranging direction of the connecting electrodes, to the connecting electrodes;

embrocating resist on the substrate, exposing and developing the substrate, forming openings between the connecting electrodes, and revealing parts of the coil springs in between the connecting electrodes;

eliminating the revealed parts of the coil springs by etching;

eliminating the resist; and

connecting the connecting electrodes to a plurality of connecting pads of a function element device through the coil springs.

According to a fifth aspect of the present invention, there is provided a production method of a semiconductor device, in a wafer on which a plurality of function element devices having connecting pads are set, comprising steps of:

connecting a plurality of coil springs, which are set on each of the connecting pads arranged in a line so that each axial of the coil springs substantially runs in a direction parallel to the arranging direction of the connecting pads, to the connecting pads;

cutting each part of the coil springs in between the connecting pads by laser;

cutting the wafer into each of the function element devices; and

connecting the cut function element device to a plurality of connecting electrodes of a substrate through the coil springs.

According to a sixth aspect of the present invention, there is provided a production method of a semiconductor device, in a substrate having connecting electrodes, comprising steps of:

connecting a plurality of coil springs, which are set on each of the connecting electrodes arranged in a line so that each axial of the coil springs substantially runs in a direction parallel to the arranging direction of the connecting electrodes, to the connecting electrodes;

cutting each part of the coil springs in between the connecting electrodes by laser; and

connecting the connection electrodes to a plurality of connecting pads of a function element device through the coil springs.

According to a seventh aspect of the present invention, there is provided a production method of a semiconductor device, when a silicon template is prepared and a wafer or a substrate is set on the silicon template so that a plurality of connecting pads or a plurality of connecting electrodes get opposed to the silicon template, comprising steps of:

forming a plurality of V-shaped grooves on a surface of the silicon template so as to be matched with areas to which a plurality of coil springs on the surface of the wafer or on the surface of the substrate are to be set;

setting a plurality of coil springs cut into a length not greater than a width of each of the connecting pads or the connecting electrodes to the V-shaped grooves;

setting the wafer or the substrate on the silicon template so as to contact the connecting pads or the connecting electrodes to the coil springs; and

connecting the coil springs to the connecting pads or the connecting electrodes.

In the present invention, there are formed the V-shaped grooves running in an arbitrary direction on the silicon template so as to correspond to the connecting pads and(or) the connecting electrodes. Thereby, it is possible to adjust the position of the coil springs with accuracy. Therewith, it is possible to adjust the axial of each of the coil springs with respect to each of the connecting pads or the connecting electrodes. Therefore, it is possible to optimize stress on each of the connecting pads or the connecting electrodes.

According to an eighth aspect of the present invention, there is provided a production method of a semiconductor device comprising steps of:

cutting a plurality of coil springs into a prescribed length;

setting the cut coil springs on each of a plurality of connecting pads of a plurality of wafer-type function element devices;

connecting the coil springs to the connecting pads;

dicing the wafer into each of the function element devices;

connecting the connecting pads of the cut function element device to a plurality of connecting electrodes of a substrate through the coil springs, and mounting the function element device on the substrate.

In the present invention, the wafer is diced after the coil springs are connected to the plurality of connecting pads on the surface of the wafer. Thereby, it is possible to manufacture semiconductor devices effectively.

According to a ninth aspect of the present invention, there is provided a production method of a semiconductor device comprising steps of:

cutting a plurality of coil springs into a prescribed length;

setting the cut coil springs on each of a plurality of connecting electrodes of a substrate;

connecting the coil springs to the connecting electrodes;

connecting the connecting electrodes to a plurality of connecting pads of a function element device through the coil springs, and mounting the function element device on the substrate.

According to a tenth embodiment of the present invention, there is provided a production method of a semiconductor device comprising steps of:

cutting a plurality of coil springs into a prescribed length, and forming a plurality of first and second coil springs;

setting the first coil springs on each of a plurality of connecting pads of a function element device so that each axial of the first coil springs substantially runs in a direction vertical to a face on which the connecting pads are formed, and therewith, setting the second coil springs on each of a plurality of connecting electrodes of a substrate so that each axial of the second coil springs substantially runs in a direction vertical to a face on which the connecting electrodes are formed;

connecting the first coil springs to the connecting pads, and therewith, connecting the second coil springs to the connecting electrodes;

connecting the first coil springs and the second coil springs by entwining them mutually;

executing an electrical inspection to the function element device;

when the function element device is non-defective goods, heating the first and the second coil springs, and joining the first coil springs to the second coil springs; and

when the function element device is defective goods, separating the first coil springs from the second coil springs.

By entwining the first and the second coil springs mutually, the function element device can be tentatively connected to the substrate. After the tentative connection, the electrical inspection is executed. When a faulty point is found in the connection area of the function element device, or between the function element device and the substrate, the entwined first and second coil springs are unraveled as described above. Thereby, it is possible to peel the function element device from the substrate without heating and damaging the connection area between the function element device and the substrate. Therefore, it becomes easier to reconnect the peeled function element device and the substrate. Further, it is possible to obtain a semiconductor device having flip chip bonding structure wherein reliability of connection is high even after the reconnection.

According to an eleventh aspect of the present invention, there is provided a coil spring cutting jig for cutting a plurality of coil springs that are to be connected to a function element device or a substrate, comprising a box whose internal height is larger than an external diameter of each of the coil springs, wherein:

a plurality of hole sections whose internal diameter is larger than the external diameter of each of the coil springs are arranged in a line on at least one side of the box, and the coil springs can be inserted and taken out through the hole sections; and

a plurality of slit-shaped openings are set at prescribed intervals on a side substantially vertical to the side on which the hole sections are arranged and substantially parallel to the arranging direction of the hole sections.

In the present invention, the coil springs are housed in the box and the laser is irradiated from the external of the box. Thereby, it is possible to cut the plenty of coil springs into a prescribed length effectively.

According to a twelfth aspect of the present invention, there is provided a coil spring cutting jig for cutting a plurality of coil springs that are to be connected to a function element device or a substrate, comprising:

a plurality of tubes which comprise transparent material transmitting laser, into which the coil springs can be housed, and whose internal diameter is larger than an external diameter of each of the coil springs; and

a tube holder joining and housing the plurality of tubes.

In the present invention, by cutting the coil springs as they are housed in the tubes, it is possible to cut the plenty of coil springs into a prescribed length effectively. Therewith, it is possible to maintain the cut coil springs with the arranging state. Further, the handling of the cut coil springs becomes easier.

According to a thirteenth aspect of the present invention, there is provided coil spring guiding jig for guiding a plurality of coil springs onto a plurality of connecting pads on a function element device or a plurality of connecting electrodes on a substrate, comprising:

a housing including a plurality of guide holes whose internal diameter is larger than each of the coil springs and each of which has a plurality of openings above and below thereof; and

a boost-up pin that is set at the bottom of the housing and that can be intruded into each of the guide holes, wherein:

each of the guide holes is set so as to be matched with a position of each of the connecting pads or each of the connecting electrodes.

In the present invention, the guide holes are set so as to be matched with the positions of the connecting pads or the connecting electrodes. Then, the coil springs are housed into each of the guide holes, and the foot of each of the housed coil springs is pressed by the boost-up pin. Thereby, the coil springs are boosted up and stuck out one by one from the openings set at the top of the guide holes. Therefore, it is possible to guide the coil springs to the connecting pads or the connecting electrodes at a time. Further, by using the coil spring guiding jig with the above-described coil spring cutting jig, it is possible to shift the coil springs housed in the coil spring cutting jig to the coil spring guiding jig as the coil springs are arranged. Therefore, it is possible to manufacture semiconductor devices effectively.

### BRIEF DESCRIPTION OF THE DRAWINGS

The objects and features of the present invention will become more apparent from the consideration of the following detailed description taken in conjunction with the accompanying drawings in which:

FIG. 1 is a cross sectional view showing a configuration of a conventional semiconductor device;

FIG. 2 is a side view showing a configuration of a semiconductor device 46a according to a first embodiment of the present invention;

FIG. 3A is a plan view showing a configuration of a cutting jig 29 used in the production method of the semiconductor device 46a according to the first embodiment;

FIG. 3B is a cross sectional view showing the configuration of the cutting jig 29 used in the production method of the semiconductor device 46a according to the first embodiment;

FIG. 3C is a front view showing the configuration of the cutting jig 29 used in the production method of the semiconductor device 46a according to the first embodiment;

FIGS. 4A and 4B are cross sectional views each showing a configuration of a coil holder 37 that serve as a coil spring guiding jig according to the first embodiment;

FIG. 5 is a plan view showing a configuration of a wafer 24 on which plenty of function element chips 1 are formed in the semiconductor device 46a according to the first embodiment;

FIG. 6 is a side view showing a configuration of the function element chip 1 according to the first embodiment;

FIG. 7 is a side view showing a configuration of a semiconductor device 46b according to a second embodiment of the present invention;

FIG. 8A is a plan view showing a shape of a coil spring 67 according to the second embodiment;

FIG. 8B is a side view showing the shape of the coil spring 67 according to the second embodiment;

FIG. 9 is a side view showing a configuration of a semiconductor device 46c according to a deformed example of the second embodiment;

FIG. 10 is a side view showing a configuration of a semiconductor device 46d according to a third embodiment of the present invention;

FIG. 11A is a cross sectional view showing a configuration of a cutting jig 47 according to the third embodiment;

FIG. 11B is a front view showing the configuration of the cutting jig 47 according to the third embodiment;

FIG. 12 is a side view showing a configuration of a semiconductor device 46e according to a fourth embodiment of the present invention;

FIG. 13A is a side view showing a first process of a production method of the semiconductor device 46e according to the fourth embodiment;

FIG. 13B is a side view showing a second process of the production method of the semiconductor device 46e according to the fourth embodiment;

FIG. 13C is a side view showing a third process of the production method of the semiconductor device 46e according to the fourth embodiment;

FIG. 14 is a side view showing a configuration of a semiconductor device 46f according to a fifth embodiment of the present invention;

FIG. 15 is a side view showing a production method of the semiconductor device 46f according to the fifth embodiment;

FIG. 16 is a side view showing a production method of a semiconductor device according to a deformed example of the fifth embodiment;

FIG. 17 is a side view showing a configuration of a semiconductor device 46g according to a sixth embodiment of the present invention;

FIG. 18 is a cross sectional view showing a production method of the semiconductor device 46g according to the sixth embodiment;

FIG. 19 is a side view showing a configuration of a semiconductor device 46h according to a seventh embodiment of the present invention;

FIG. 20 is a side view showing a shape of a vertical coil spring 69 according to the seventh embodiment;

FIGS. 21A and 21B are side views each showing a shape of a coil spring according to a first deformed example of the seventh embodiment;

FIGS. 22A, 22B and 22C are side views each showing a shape of a coil spring according to a second deformed example of the seventh embodiment;

FIGS. 23A, 23B and 23C are side views each showing a shape of a vertical coil spring according to a second deformed example of the seventh embodiment;

FIG. 24 is a side view showing a configuration of a semiconductor device 46i according to an eighth embodiment of the present invention;

FIG. 25 is a cross sectional view showing a configuration of a semiconductor device 46j according to a ninth embodiment of the present invention;

FIG. 26 is a cross sectional view showing a configuration of a semiconductor device 46k according to a tenth embodiment of the present invention;

FIG. 27A is a side view showing a configuration of a semiconductor device according to an eleventh embodiment of the present invention; and

FIG. 27B is a side view showing a production method of the semiconductor device according to the eleventh embodiment of the present invention.

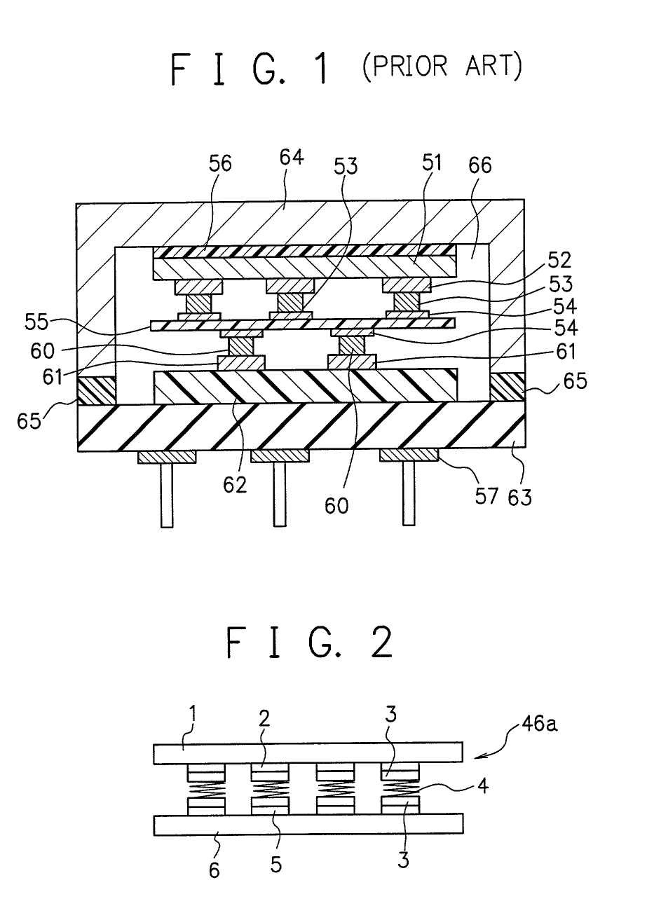

### DESCRIPTION OF THE PREFERRED EMBODIMENTS

Referring now to the drawings, embodiments of the present invention will be explained in detail. First, an explanation will be given of a first embodiment of the present invention. FIG. 2 is a side view showing a configuration of a semiconductor device 46a according to the first embodiment. The semiconductor device 46a comprises a plurality of topside substrate electrodes 5 on a top surface of a substrate 6. A metal layer 3 about 0.01 to 0.1 μm thick is formed on each of the topside substrate electrodes 5. On each of the metal layers 3, there is made a vertical coil spring 4, which is connected to the topside substrate electrode 5 through the metal layer 3. The vertical coil spring 4 has spiral shape, and the axial thereof is vertical to the substrate 6.

On an undersurface of a function element chip 1, a plurality of chip electrodes 2 are made. Besides, a metal layer 3 is formed under the chip electrode 2. Each of the chip electrodes 2 is connected to the vertical coil spring 4 through the metal layer 3. In this way, the function element chip 1 is connected to the substrate 6 through the chip electrodes 2, vertical coil springs 4 and topside substrate electrodes 5 by means of flip chip bonding. The function element chip 1 has a configuration wherein wiring is formed on a backing material that is, made of Si, GaAs, LiTaO₃, LiNbO₃, or crystal etc. Besides, it is preferable to use one selected from a printed board, organic material board or alumina board such as a flexible board, glass ceramic board, and ceramic board such as a glass board for the substrate 6, but not limited to those. Further, a thin membrane layer that comprises Ti and Pd, Cr and Pd, or Cr and Cu etc. are preferably used as the metal layer 3. Moreover, a conductive adhesive layer may be applied thereto.

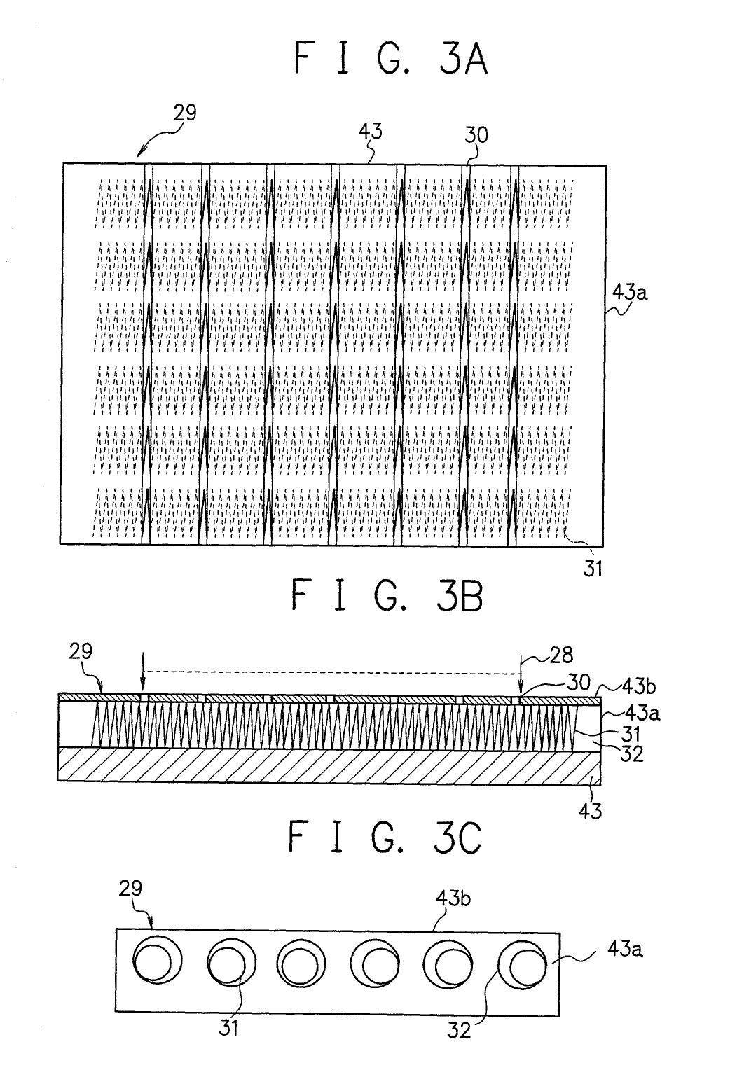

Next, an explanation will be given of a cutting jig 29 and a coil holder 37 used in manufacturing the semiconductor device 46a according to this embodiment. FIGS. 3A to 3C show a configuration of the cutting jig 29 used in manufacturing the semiconductor device 46a. FIG. 3A shows the plan view thereof, FIG. 3B shows the cross sectional view thereof, and FIG. 3C shows the front view thereof. The cutting jig 29 cuts a plurality of continuous coil springs, which are more than several times longer than the width of the chip electrode 2, into the width corresponding to that of the chip electrode 2 formed on the undersurface of the function element chip 1 or the width corresponding to distance between the function element chip 1 and the substrate 6 shown in FIG. 2. Thereby, plenty of divided coil springs (not shown) are made.

As shown in FIGS. 3A to 3C, the cutting jig 29 is provided with a box 43 whose internal height is larger than an external diameter of a continuous coil spring 31. A plurality of jig holes 32 each of whose diameter is larger than the external diameter of the continuous coil spring 31 are made on one side 43a of the box 43. The jig holes 32 are arranged in a line corresponding to the forming pitch of the chip electrodes 2 on the function element chip 1. Besides, a plurality of slit-shaped jig openings 30 are formed on a top surface 43b that is vertical to the side 43a and parallel to the arrangement direction of the jig holes 32. The plural jig openings 30 are formed at regular intervals in the arrangement direction of the jig holes 32. The intervals are approximately equal to the width of the chip electrode 2 or the distance between the function element chip 1 and the substrate 6.

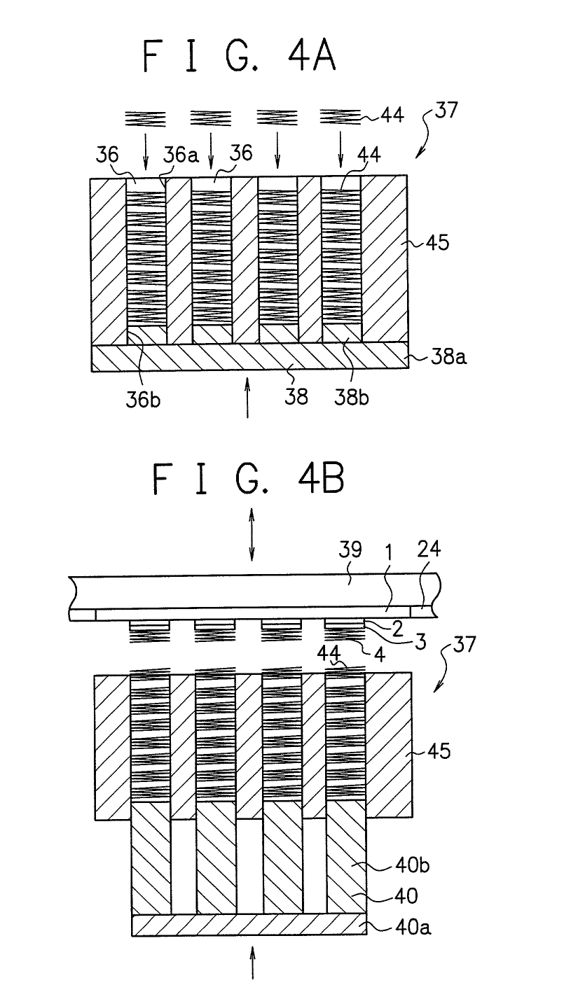

FIGS. 4A and 4B are cross sectional views each showing a configuration of the coil holder 37 used as the coil spring guiding jig according to this embodiment. FIG. 4A shows an operation of housing divided coil springs 44 into the coil holder 37. FIG. 4B shows an operation of guiding the divided coil springs 44 to the function element chip 1 from the coil holder 37. The coil holder 37 serves as a jig for guiding the divided coil springs 44 to the function element chip 1 or the substrate 6 in order to form the vertical coil springs 4.

As shown in FIG. 4A, the coil holder 37 is provided with a housing 45. In the housing 45, a plurality of guide holes 36 each of which has cylindrical shape are made in parallel to each other. The diameter of the guide hole 36 is a little larger than the external diameter of the coil spring 44. The intervals of the guide holes 36 are equal to those of the jig holes 32 in the cutting jig 29 shown in FIGS. 3A to 3C, and equal to those of the chip electrodes 2. The guide hole 36 penetrates the housing 45. Besides, each guide holes 36 has an upper side opening 36a and a bottom side opening 36b at both ends thereof. As shown in FIG. 4A, the housing 45 houses and holds the plural coil springs 44 in each of the guide holes 36. Besides, a stopper 38 is placed at the foot of the housing 45. The stopper 38 functions so as not to drop the coil springs 44 held in the guide holes 36 from the bottom side openings 36b. The stopper 38 has a backing 38a and a plurality of projections 38b. The plurality of projections 38b are placed on one side of the backing 38a so as to be matched with the guide holes 36. Further, the projections 38b can be put into the guide holes 36. The stopper 38 is fixed to the housing 45 by intruding the projections 38b into the bottom side openings 36b.

Besides, the stopper 38 can be detached from the housing 45. Further, it is possible to fit on a boost-up pin 40 to the housing 45 as a substitute for the stopper 38. As shown in FIG. 4B, the boost-up pin 40 has a flat backing 40a and a plurality of pins 40b. The plurality of pins 40b are placed on one side of the backing 40a so as to be matched with the guide holes 36. Further, the pins 40b can be intruded into the guide holes 36. The boost-up pin 40 is inserted into the guide holes 36 from the bottom side openings 36b. Then, the boost-up pin 40 pushes up the coil springs 44 by pressing the lower ends of the coil springs 44 housed in the guide holes 36. Thereby, the coil springs 44 are stuck out of the upper side openings 36a of the guide holes 36.

Next, an explanation will be given of a production method of the semiconductor device 46a according to this embodiment. As shown in FIGS. 3a to 3c, first, the continuous coil springs 31 are inserted into the box 43 of the cutting jig 29 through the jig holes 32. After that, laser 28 such as YAG (Yttrium Aluminum Garnet) laser or carbon dioxide laser is scanned at the position of the jig openings 30 or irradiated on all over the top surface 43b from above the top surface 43b of the box 43. Then, the laser 28 is taken in the inside of the box 43 through the jig openings 30. Thereby, the continuous coil springs 31 housed in the box 43 are cut into some pieces, and the plurality of coil springs 44 are made.

Secondly, as shown in FIG. 4a, the stopper 38 is mounted at the foot of the coil holder 37. After that, the side where the upper side openings 36a of the coil holder 37 are formed is contacted on the side 43a of the cutting jig 29 so as to match the position of the upper side openings 36a of the coil holder 37 with that of the jig holes 32 (refer to FIG. 3C) of the cutting jig 29. Then, the coil springs 44 are shifted from the box 43 of the cutting jig 29 to the guide holes 36 of the coil holder 37 through the jig holes 32 and the upper side openings 43a. Thereby, a plurality of the coil springs 44 are housed in each of the guide holes 36, and piled up in a line along the axial of the guide holes 36.

Thirdly, as shown in FIG. 4B, the stopper 38 is detached from the housing 45. After that, as a substitute for the stopper 38, the boost-up pin 40 is attached to the housing 45.

FIG. 5 is a plan view showing a configuration of a wafer 24, on which plenty of the function element chips 1 are formed. A plurality of the chip electrodes 2, each on which barrier metal is formed, are set on the surface of each of the function element chips 1.

As shown in FIG. 4B, fist, a heating-absorbing head 39 executes heating, pressurization and positioning to the wafer 24 while absorbing and holding the wafer 24. Thereby, the wafer 24 is absorbed and positioned above the coil holder 37. Secondly, by shifting the boost-up pin 40 upward on the coil holder 37, the pins 40b press the foot of the coil springs 44 piled up in a line in the guide holes 36 and boost up the coil springs 44. Thereby, the coil springs 44 put in the top position in the guide holes 36 are stuck out of the upper side openings 36a of the guide holes 36.

Thirdly, the stuck-out coil springs 44 are contacted to the chip electrodes 2 on the function element chip 1 on the wafer 24. Then, the heating-absorbing head 39 executes heating reflow to the metal layers 3. Then, the coil springs 44 are joined to the chip electrodes 2. Thereby, the vertical coil springs 4 are formed on the chip electrodes 2. By repeating the above operations, the vertical coil springs 4 are formed on the plenty of the function element chips 1 on the wafer 24.

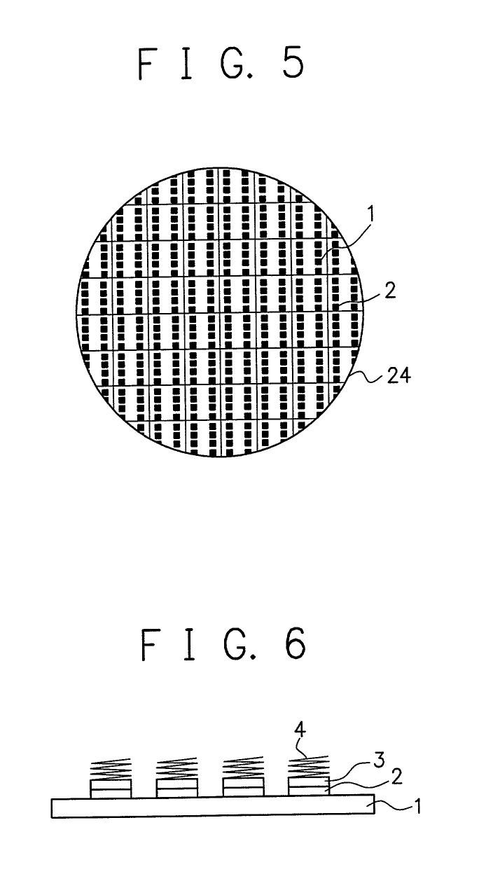

Fourthly, the wafer 24 is diced and divided into each of the function element chips 1. FIG. 6 is a side view showing a configuration of the function element chip 1 that has the vertical coil springs 4 on the face thereof formed by the above operations. A plurality of the chip electrodes 2 are formed on the face of the function element chip 1. The metal layers 3 are formed on the chip electrodes 2. The vertical coil springs 4 are connected to the chip electrodes 2 through the metal layers 3.

Fifthly, the vertical coil springs 4 on the function element chip 1 shown in FIG. 6 is contacted to the metal layers 3 on the substrate 6 that has the top side substrate electrodes 5 on which the metal layers 3 are formed as shown in FIG. 2. After that, heating reflow is executed to the metal layers 3 on the topside substrate electrodes 5. Then, the vertical coil springs 4 are connected to the topside substrate electrodes 5 through the metal layers 3. Thereby, there is obtained the semiconductor device 46a.

In this embodiment, the function element chip 1 is connected to the substrate 6 through the vertical coil springs 4. Thereby, it is possible to absorb the stress concentration caused by the thermal expansion difference between the materials forming the function element chip 1 and forming the vertical coil springs 4 by the spring characteristics of the vertical coil springs 4. Therefore, it is possible to obtain flip chip bonding structure wherein reliability of connection is high. Besides, in selecting materials used for the function element chips 1 and the substrate 6, there is no need to take account of the difference of thermal expansion coefficient. Therefore, it is possible to enhance design flexibility of a semiconductor device and to make it easy to design a semiconductor device.

Besides, by the cutting jig 29, the continuous coil springs 31 can be cut into divided coil springs 44 at a time. Therefore, it is possible to produce the coil springs 44 of equal length with a high degree of accuracy and efficiency.

Further, by the coil holder 37, the microscopic coil springs 44 can be guided onto the chip electrodes 2 of the function element chip 1 easily and efficiently. Thereby, it is possible to connect a plurality of the coil springs 44 to the function element chips 1 at a time. Consequently, it is possible to form the vertical coil springs 4 efficiently with a low cost.

In this embodiment, there is shown an example that the wafer 24 is diced into each of the function element chips 1 after the vertical coil springs 4 are formed on the function element chips 1. Incidentally, it is also possible to form the vertical coil springs 4 on the function element chips 1 after the wafer 24 is diced into each of the function element chips

In addition, in this embodiment, there is shown an example that the vertical coil springs 4 are connected to the substrate 6 after the vertical coil springs 4 are formed on the function element chips 1. Incidentally, by the same method as shown in this embodiment, it is possible to connect the function element chips 1 to the vertical coil springs 4 after forming the vertical coil springs 4 on the top side substrate electrodes 5 on the substrate 6.

Further, in this embodiment, there is shown an example of connecting the coil springs 44 to the metal layers 3 by means of the heating reflow. Incidentally, it is possible to connect them by means of thermal compression bonding, ultrasonic or scrub etc. other than the heating reflow.

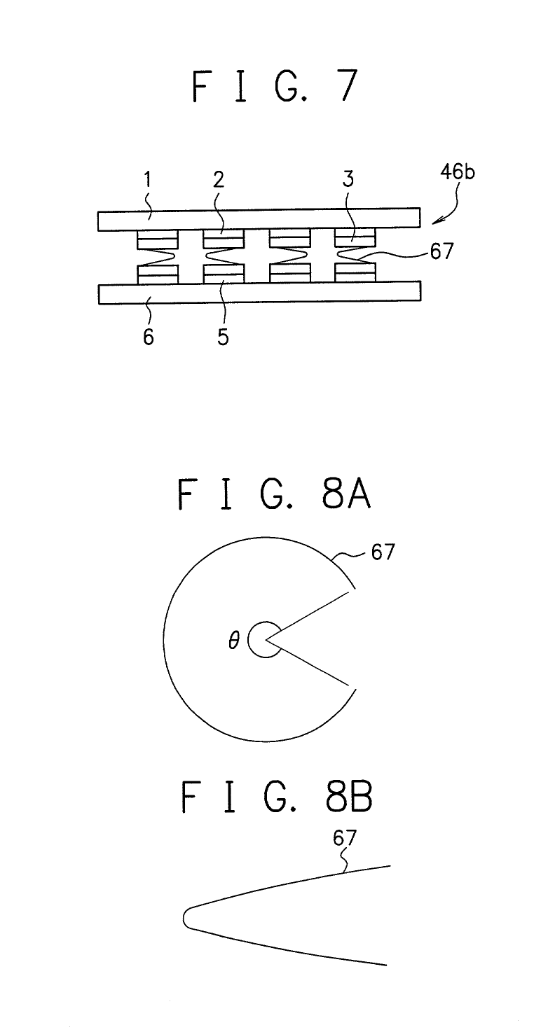

Next, an explanation will be given of a second embodiment of the present invention. FIG. 7 is a side view showing a configuration of a semiconductor device 46b according to this embodiment. Besides, FIG. 8A is a plan view showing a shape of a coil spring 67 in the semiconductor device 46b, and FIG. 8B is the side view thereof. As shown in FIG. 7, in the semiconductor device 46b, there are placed the coil springs 67 cut into length not greater than 1 pitch as substitutes for the vertical coil springs 4 in the semiconductor 46a of the first embodiment shown in FIG. 2. The chip electrodes 2 of the function element chip 1 are connected to the topside substrate electrodes 5 of the substrate 6.

As shown in FIGS. 8A and 8B, as viewed from the axial, the angle between the both ends of the coil spring 67 (hereinafter, referred to as the center angle θ) is not greater than 360 degrees. Namely, when 1 pitch is 360 degrees, the center angle θ of the coil spring is not greater than 1 pitch, which is used in this embodiment. As viewed from the axial, the shape of the coil spring 67 shows a sectoral circumference as shown in FIG. 8A. On the other hand, as viewed from the direction vertical to the axial, the shape of the coil spring 67 shows a V-shaped one as shown in FIG. 8B. The configuration of the semiconductor device 46b is the same as that of the semiconductor 46a in the above-described first embodiment except for the coil spring 67.

The coil spring 67 is formed by cutting the continuous coil spring 31 into the length not greater than 1 pitch by, for example, the cutting jig 29 shown in FIGS. 3A to 3C. The production method of the semiconductor device 46b of this embodiment is the same as that of the semiconductor device 46a of the first embodiment except for the production method of the coil spring 67.

According to this embodiment, the coil spring 67 is cut into not greater than 1 pitch. Thereby, it is possible to connect the function element chip 1 to the substrate 6 wherein less inductance and less electric noise are generated compared to the first embodiment.

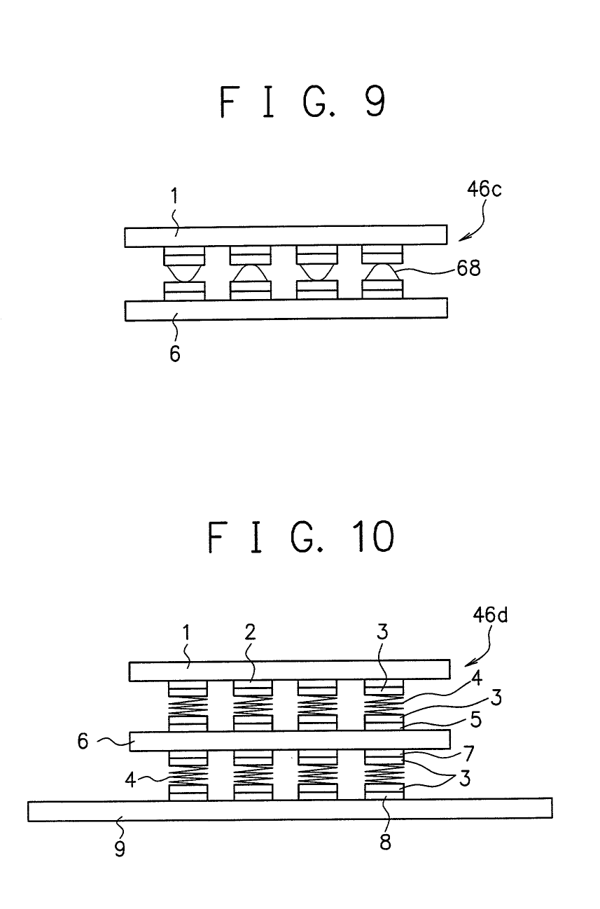

Besides, FIG. 9 is a side view showing a configuration of a semiconductor device 46c as a deformed example of this embodiment. In the semiconductor device 46c, coil springs 68 are provided as substitutes for the coil springs 67 for the semiconductor device 46b shown in FIG. 7. The coil springs 68 are the same as the coil springs 67 except that the axial runs in the parallel direction (hereinafter, referred to as in the horizontal direction) to the face of the substrate 6. Hereby, it is possible to connect the function element chip 1 to the substrate 6 in the semiconductor device 46c wherein much less inductance and much less electric noise are generated compared to the semiconductor device 46b.

Next, an explanation will be given of a third embodiment of the present invention. FIG. 10 is a side view showing a configuration of a semiconductor device 46d according to this embodiment. In the semiconductor device 46d, there is provided a configuration that a mother board 9 is connected to the semiconductor device 46a shown in FIG. 2. The mother board 9 of the semiconductor device 46a is provided with mother board electrodes 8 on its top surface. The metal layers 3 about 0.01 to 0.1 μm thick are formed on each of the mother board electrodes 8. The mother board 9 is used in order to mount the substrate 6 to which the function element chip 1 is connected. The substrate 6 is set above the mother board 9. A plurality of the topside substrate electrodes 5 and a plurality of backside substrate electrodes 7 are formed on the top surface and under surface of the substrate 6, respectively. The metal layers about 0.01 to 0.1 μm thick are formed on the top side substrate electrodes 5 and the backside substrate electrodes 7. The vertical coil springs 4 are placed between the mother board electrodes 8 and the backside substrate electrodes 7. The both ends of the vertical coil springs 4 are connected to the metal layers 3 formed on the mother board electrodes 8 and those formed on the backside substrate electrodes 7, respectively. Each of the vertical coil springs 4 has spiral shape, and the axial thereof runs in the vertical direction.

Besides, other vertical springs 4 are placed on the metal layers 3 formed on the topside substrate electrodes 5. The vertical springs 4 are connected to the topside substrate electrodes 5 through the metal layers 3. The function element chip 1 is set above the vertical coil springs 4. A plurality of the chip electrodes 2 are formed on the undersurface of the function element chip 1. The metal layers 3 are formed under the chip electrodes 2. The chip electrodes 2 are connected to the vertical coil springs 4 through the metal layers 3. In this way, the function element chip 1 is connected to the substrate 6 through the chip electrodes 2, vertical coil springs 4 and topside substrate electrodes 5 by means of flip chip bonding.

Incidentally, the materials for the function element chip 1, substrate 6 and metal layers 3 in this embodiment are the same as those in the above-described first embodiment.

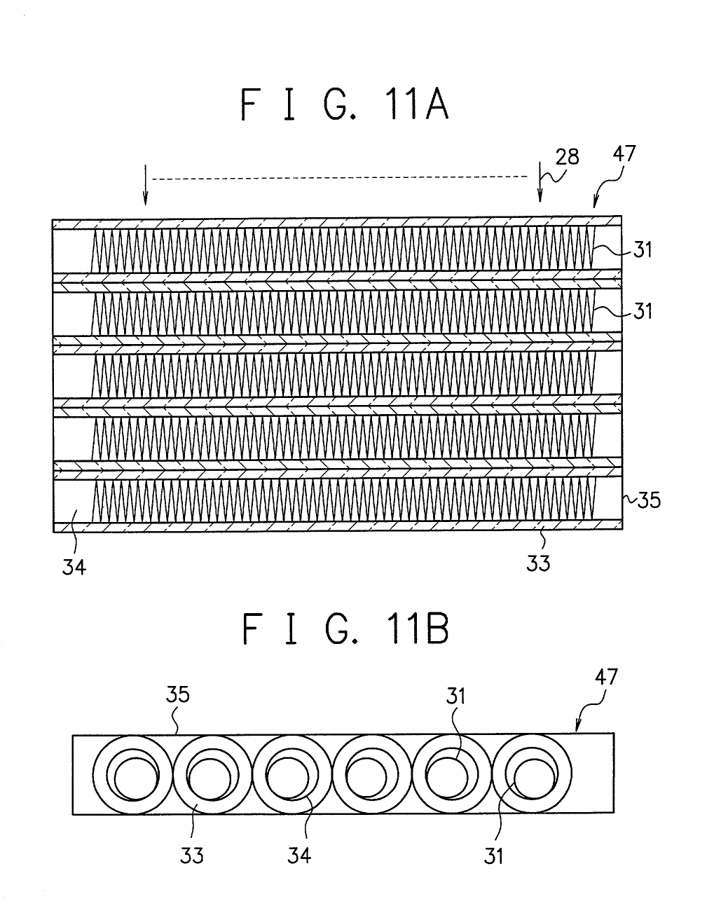

Next, an explanation will be give of a cutting jig 47 used in producing the semiconductor device 46d according to this embodiment. FIGS. 11A and 11B show a configuration of the cutting jig 47. FIG. 11A shows a cross sectional view thereof. FIG. 11B shows a front view thereof. The cutting jig 47 cuts the continuous coil springs 31 into the length corresponding to the width of the chip electrode 2 formed on the undersurface of the function element chip 1, the distance between the function element chip 1 and the substrate 6, the width of the mother board electrode 8, or the distance between the substrate 6 and the mother board 9 shown in FIG. 10. Thereby, the cutting jig 47 forms plenty of the divided coil springs 44 shown in FIG. 4A.

As shown in FIGS. 11A and 11B, the cutting jig 47 comprises a plurality of cutting jig transparent tubes 33 within a tube holder 35. The internal diameter of the cutting jig transparent tube 33 is a little larger than the external diameter of the coil spring 44. The cutting jig transparent tubes 33 are arranged in a line and in parallel to each other. The arranging pitch thereof is the same as the forming pitch of the chip electrodes 2 of the function element chip 1. The tube holder 35 and the cutting jig transparent tubes 33 are made of a transparent material through which the laser 28 can transmit. Each shape of the cutting jig transparent tubes 33 is tube like shape and has openings at the both sides thereof. Inside the cutting jig transparent tube 33 forms a tube hole 34.

Next, an explanation will be given of the production method of the semiconductor device 46d according to this embodiment. First, as shown in FIG. 11, the continuous coil springs 31 are inserted into the tube holes 34 of the cutting jig 47.

Secondly, the laser 28 is irradiated on the tube holder 35 from the direction orthogonal to the side of the cutting jig transparent tubes 33 in the axial direction of the cutting jig transparent tubes 33 at prescribed pitch. For one thing concerned with an irradiating method of the laser 28, there is a method to scan the laser 28 in the direction orthogonal to the axial of the cutting jig transparent tubes 33. The laser 28 is arranged in several lines and in the axial direction of the cutting jig transparent tubes 33. For another, there is a method to set a shielding mask (not shown) so as to cover a face of the tube holder 35 that is irradiated by the laser 28. The shielding mask has slit-shaped openings and stretches in the direction orthogonal to the axial of the cutting jig transparent tubes 33. Then, the laser 28 is irradiated on the whole shielding mask. The laser 28 transmits through the tube holder 35 and the cutting jig transparent tubes 33, reaches to the continuous coil springs 31, and cuts the continuous coil springs 31. Thereby, the coil springs 44 cut into several pieces shown in FIG. 4A are made up.

Thirdly, the upper side openings 36a of the coil holder 37 shown in FIGS. 4A and 4B are contacted to the tube holes 34 of the cutting jig 47. Then, the coil springs 44 housed in the tube holes 34 are shifted to the guide holes 36 of the coil holder 37.

Fourthly, as shown in FIG. 4B and FIG. 10, by using the coil holder 37 in the same way as the above-described first embodiment, the coil springs 44 are connected to the mother board electrodes 8 on the mother board 9 through the metal layers 3, and thereby, the vertical coil springs 4 are formed. Fifthly, the substrate 6 is set above the vertical coil springs 4. Then, the backside substrate electrodes 7 having metal layers 3 and formed on the undersurface of the substrate 6 are connected to the top of the vertical coil springs 4.

Sixthly, by applying the same method as the above-described first embodiment, the vertical coil springs 4 are formed on the substrate 6. The function element chip 1 is set above the coil springs 4. Then, the chip electrodes 2 formed on the undersurface of the function element chip 1 are connected to the vertical coil springs 4 formed above the substrate 6 through the metal layers 3. In this way, the semiconductor device 46d according to this embodiment is formed.

The semiconductor device 46d according to this embodiment has vertical coil springs 4 between the function element chip 1 and the substrate 6, and between the substrate 6 and the mother board 9. Thereby, it is possible to relieve stress caused by the thermal expansion difference between the function element chip 1 and the substrate 6, and between the substrate 6 and the mother board 9. Therefore, it is possible to enhance reliability of connection between the function element chip 1 and the substrate 6, and between the substrate 6 and the mother board 9. Further, it is possible to enhance design flexibility of a semiconductor device.

Besides, the cutting jig 47 is used in this embodiment. Thereby, it is possible to form the coil springs 44 with a high degree of accuracy at a time. Further, by shifting all of the plenty of coil springs 44 housed in the tube holes 34 of the cutting jig 47 into the coil holder 37, it is possible to easily handle the coil springs 44 that are hard to handle because of their imperceptibility.

Incidentally, while there is shown an example of using the cutting jig 47 in order to cut the continuous coil springs 31 and form the coil springs 44 in this embodiment, it is also possible to use the cutting jig 29 as shown in FIGS. 3A to 3C. Besides, it is possible to use the cutting jig 47 in the above-described first and second embodiments.

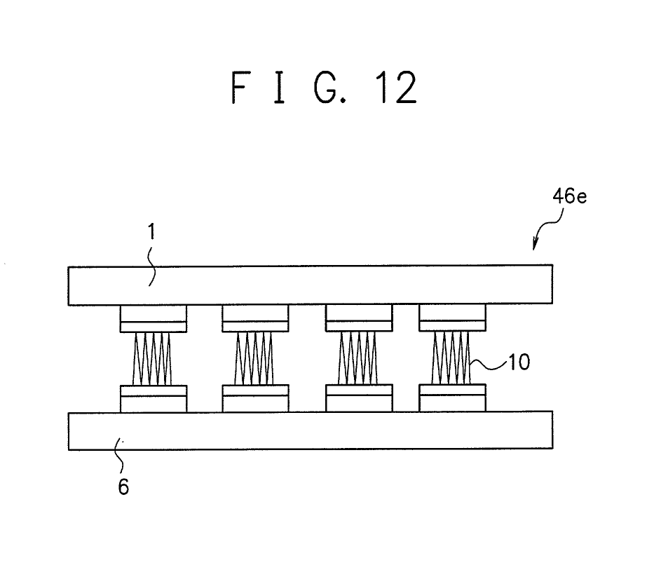

Next, an explanation will be given of a fourth embodiment of the present invention. FIG. 12 is a side view showing a configuration of a semiconductor device 46e according to this embodiment. The semiconductor device 46e has a configuration that horizontal coil springs 10 are used as substitutes for the vertical coil springs 4 used in the semiconductor device 46a in the first embodiment shown in FIG. 2. The horizontal coil springs 10 are the same as the coil springs 44 except that the axial runs in the horizontal direction. The function element chip 1 is connected to the substrate 6 through the horizontal coil springs 10. The configuration of the semiconductor device 46e is the same as that of the semiconductor device 46a in the first embodiment shown in FIG. 2 except for the horizontal coil springs 10.

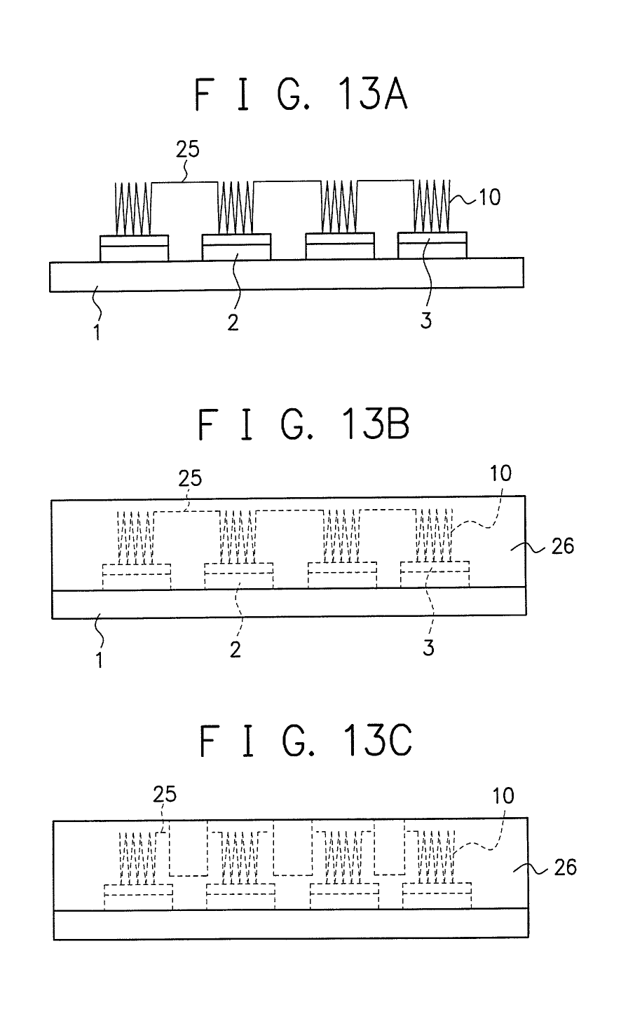

Next, an explanation will be given of the production method of the semiconductor device 46e according to this embodiment. FIGS. 13A to 13C are side views that shows the production method of the semiconductor device 46e in order of its manufacturing process. First, as shown in FIG. 13A, the chip electrodes 2 are formed on the function element chip 1 on the wafer 24 shown in FIG. 5 and the metal layers 3 are formed thereon. Then, the horizontal coil springs 10 connected to each other by coil spring connecting leads 25 are arranged so that the axial runs in a direction parallel to the face of the function element chip 1 (namely, in a horizontal direction). After that, by executing heating reflow to the metal layers 3, the horizontal coil springs 10 are connected to the chip electrodes 2.

Secondly, as shown in FIG. 13B, photosensitive resist 26 is embrocated on the function element chip 1 so as to cover the chip electrodes 2, the metal layers 3 and a plurality of the horizontal coil springs 10 connected to each other by the coil spring connecting leads 25. Then, by developing the photosensitive resist 26 after exposing it, the coil spring connecting leads 25 are exposed from the photosensitive resist 26.

Thirdly, as shown in FIG. 13C, the coil spring connecting leads 25 are eliminated by etching. Thereby, each of the horizontal coil springs 10 is separated. In this process, the horizontal coil springs 10 are shielded from etching by the photosensitive resist 26. Then, the photosensitive resist 26 is eliminated, and the wafer 24 is diced into function element chips 1.

After that, as shown in FIG. 12, the semiconductor device 46e is formed by connecting the substrate 6 to the horizontal coil springs 10.

The materials for the function element chip 1, substrate 6 and metal layers 3 used in the semiconductor device 46e shown in this embodiment are the same as those in the first embodiment. Besides, in this embodiment, there is shown an, example of connecting the horizontal coil springs 10 to the metal layers 3 by heating reflow. However, it is as well possible to make the connection by means of thermo compression bonding, ultrasonic, scrub etc.

In this embodiment, the function element chip 1 is connected to the substrate 6 through the horizontal coil springs 10. Thereby, stress concentration on connecting areas caused by the thermal expansion difference between the function element chip 1 and the substrate 6 is absorbed by the spring characteristics of the horizontal coil springs 10. Therefore, it is possible to enhance reliability of flip chip bonding between the function element chip 1 and the substrate 6. In addition, it becomes easy to select the materials for the function element chip 1 and the substrate 6.

Besides, compared to the first embodiment, the horizontal coil springs 10 are connected to the chip electrodes 2 and the topside substrate electrodes 5 at several points, respectively. Thereby, it is possible to absorb stress acting in a horizontal direction effectively. Besides, it is possible to enhance reliability of connection between the horizontal coil springs 10 and the chip electrodes 2, and between the horizontal coil springs 10 and the topside substrate electrodes 5. Further, electric noise generated at the horizontal coil springs 10 is reduced.

Further, in this embodiment, the horizontal coil springs 10 connected to each other by the coil spring connecting leads 25 can be joined to a plurality of the chip electrodes 2 at a time. After that, the coil springs connecting leads 25 are eliminated. Thereby, it is possible to form the horizontal coil springs 10 on each of the chip electrodes 2 with a high degree of accuracy and efficiency at a lower cost.

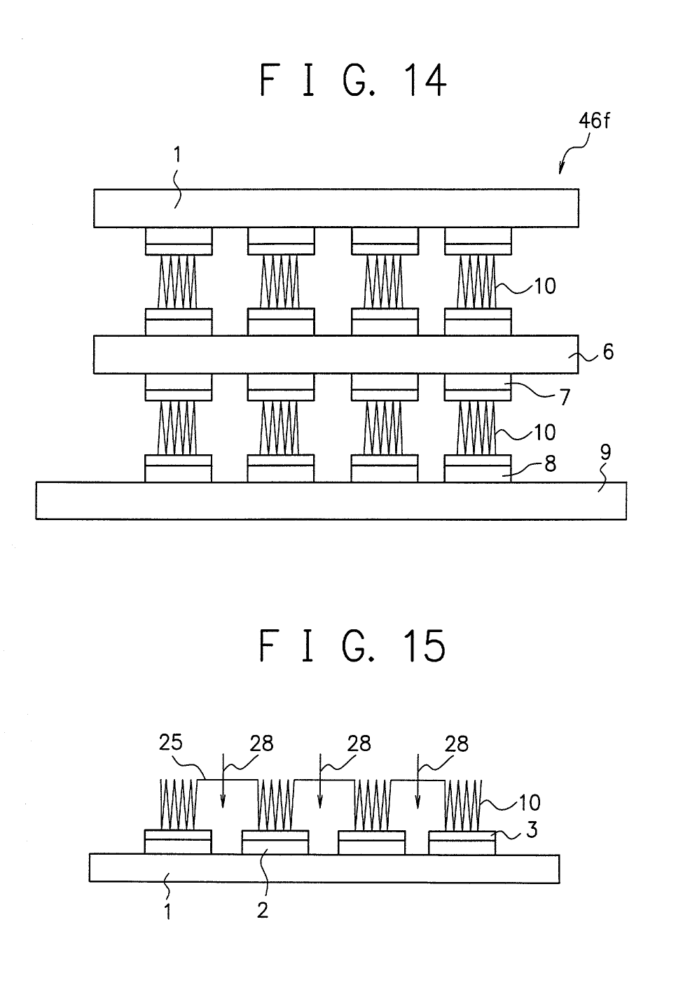

Next, an explanation will be given of a fifth embodiment of the present invention. FIG. 14 is a side view showing a configuration of a semiconductor device 46f in this embodiment. The semiconductor device 46f has the same configuration as that of the semiconductor device 46d except for the horizontal coil springs 10 substituting for the vertical coil springs 4 in the semiconductor device 46d in the third embodiment shown in FIG. 10.

Next, an explanation will be given of a production method of the semiconductor device 46f according to this embodiment. FIG. 15 is a diagram illustrating the production method of the semiconductor device 46f. First, as shown in FIG. 15, the chip electrodes 2 are formed on the function element chip 1 on the wafer 24 shown in FIG. 5. Then, the metal layers 3 are formed on the chip electrodes 2. Secondly, on the metal layers 3, a plurality of the horizontal coil springs 10 connected to each other by the coil spring connecting leads 25 are set so that the axial runs in a horizontal direction. Thirdly, the horizontal coil springs 10 are connected to the chip electrodes 2 by executing heating reflow to the metal layers 3.

Fourthly, by irradiating the laser 28 such as YAG laser or carbon dioxide laser to the coil spring connecting leads 25, the coil spring connecting leads 25 are cut. Thereby, the horizontal coil springs 10 are separated. Fifthly, the wafer 24 is diced into each of the function element chips 1.

On the other hand, by the same method as that shown in FIG. 15, other horizontal coil springs 10 are formed on the mother board electrodes 8 (refer to FIG. 10) on the mother board 9.

Sixthly, as shown in FIG. 14, the substrate 6 is set above the mother board 9. Then, the backside substrate electrodes 7 formed on the undersurface of the substrate 6 are connected to the horizontal coil springs 10 on the mother board electrodes 8. Seventhly, the function element chip 1 on which the horizontal coil springs 10 are formed by the above-described process is set above the substrate 6. Then, the horizontal coil springs 10 are connected to the top side substrate electrodes 5 formed on the top surface of the substrate 6. Thereby, the semiconductor device 46f is formed.

According to this embodiment, the mother board 9 is connected to the substrate 6 through the horizontal coil springs 10. Thereby, the horizontal coil springs 10 can absorb the thermal expansion difference between the mother board 9 and the substrate 6. Therefore, it is possible to enhance reliability of connection. Besides, compared to the semiconductor device 46d in the third embodiment, there is obtained a semiconductor device capable of absorbing stress acting in a horizontal direction in which generation of electric noise is reduced, and further, reliability of connection is excellent.

Besides, in this embodiment, the laser 28 cuts the coil spring connecting leads 25. Thereby, compared to the fourth embodiment, it is possible to simplify the necessary process in cutting the coil spring connecting leads 25.

Incidentally, in this embodiment, there is shown a method of cutting the coil spring connecting leads 25 by the laser 28. Further, it is possible to produce the semiconductor device 46f by means of cutting the coil spring connecting leads 25 by etching shown in the fourth embodiment. Besides, it is also possible to produce the semiconductor device 46e shown in the fourth embodiment by the method of cutting the coil spring connecting leads 25 by the laser 28 as shown in this embodiment.

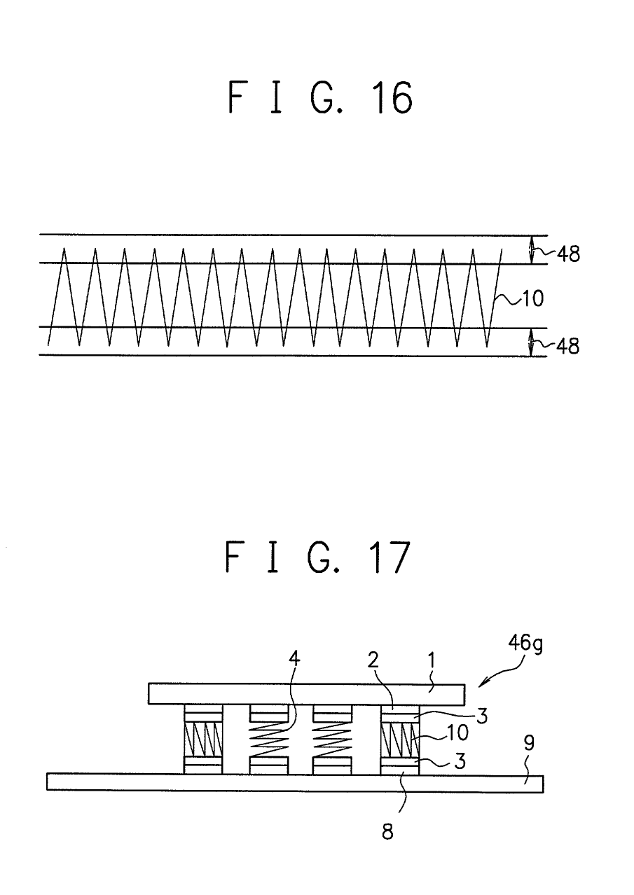

FIG. 16 is a pattern diagram showing a production method of a semiconductor device as a deformed example of the fifth embodiment. In this deformed example, metal that has good wettability is previously plated on the connecting areas of the horizontal coil springs 10, namely, plating parts 48 shown in FIG. 16. It is preferable to use a metal or a metal alloy comprising more than one selected from Au, Cu, Pb, Ag, Sn and Pd to the plating metal. Further, it is also preferable to use a double-layer membrane of Sn and Pb etc. to the plating metal. The preferable thickness of the plating is about 0.2 to 10 μm. Besides, there are some plating methods applicable to this deformed example, for example, an electrolytic plating method, dip method, vapor deposition method etc. Thereby, it is possible to further improve the connection between the horizontal coil springs 10 and the chip electrodes 2, topside substrate electrodes 5, backside substrate electrodes 7 and mother board electrodes 8.

Next, an explanation will be given of a sixth embodiment of the present invention. FIG. 17 is a side view showing a configuration of a semiconductor device 46g in this embodiment. The semiconductor device 46g is made by substituting some pieces of vertical coil springs 4 used in the semiconductor 46a in the first embodiment with the horizontal coil springs 10, and substituting the substrate 6 with the mother board 9. The semiconductor device 46g has the mother board 9 on which a plurality of the mother board electrodes 8 are formed. The metal layer 3 is formed on each of the mother board electrodes 8. Besides, the vertical coil springs 4 are formed on some of the mother board electrodes 8. The horizontal coil springs 10 are formed on the rest of the mother board electrodes 8. Further, the function element chip 1, which has the chip electrodes 2 on the undersurface thereof, is set above the vertical coil springs 4 or the horizontal coil springs 10. The metal layers 3 are formed under the chip electrodes 2 of the function element chip 1. Besides, the metal layers 3 are connected to the mother board electrodes 8 through the vertical coil springs 4 or the horizontal coil springs 10. Incidentally, the function element chip 1 and the metal layers 3 are made of the same materials as those in the first embodiment.

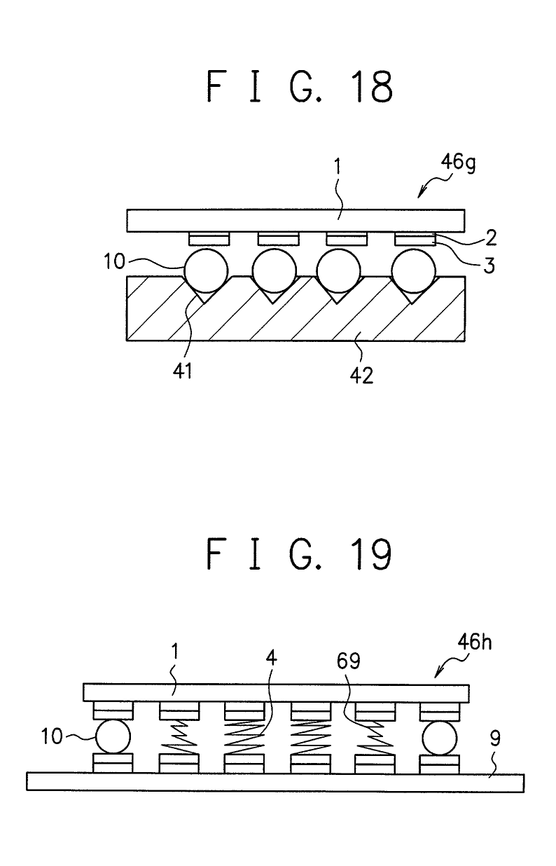

Next, an explanation will be given of a production method of the semiconductor device 46g in the sixth embodiment. FIG. 18 is a cross sectional view showing the production method of the semiconductor device 46g in this embodiment. As shown in FIG. 18, first, V-shaped grooves 41 are formed on a surface of a silicon substrate by lithography or anisotropic etching. Thereby, a silicon template 42 that has the V-shaped grooves 41 on the surface of the silicon substrate is manufactured. The arranging pattern of the V-shaped grooves 41 is the pattern that the arranging pattern of the chip electrodes 2 of the function element chip 1 is reversed.

Secondly, the horizontal coil springs 10 connected to each other by the coil spring connecting leads 25 are placed in some of the V-shaped grooves 41 on the silicon template 42 so that each axial runs in a horizontal direction. Thirdly, by using the heating-absorbing head 39 shown in FIG. 4B, the function element chip 1 having the chip electrodes 2 on the undersurface thereof is absorbed. Then, the function element chip 1 is placed above the horizontal coil springs 10 and the chip electrodes 2 are contacted to the horizontal coil springs 10. Then, some of the chip electrodes 2 are connected to the horizontal coil springs 10 by executing heating reflow to the metal layers 3 formed on the surface of the chip electrodes 2.

Fourthly, the coil spring connecting leads 25 are cut by applying the method shown in FIGS. 13B and 13C, or FIG. 15.

Fifthly, the vertical coil springs 4 are formed on the rest of the chip electrodes 2 by the same method as shown in the first embodiment. Then, the horizontal coil springs 10 and the vertical coil springs 4 formed by the above means are connected to the mother board electrodes 8 on the mother board 9. Thereby, there is formed the semiconductor device 46g shown in FIG. 17.

In this invention, the function element chip 1 is connected to the mother board 9 through the vertical coil springs 4 and the horizontal coil springs 10. Thereby, stress, which is generated by the thermal expansion difference between the materials for the function element chip 1 and the mother board 9, and whose intensity and direction vary according to the positions of connected areas, can be absorbed by the spring characteristics of the vertical coil springs 4 and the horizontal coil springs 10 effectively. Therefore, it is possible to enhance reliability of the flip chip bonding between the function element chip 1 and the mother board 9. Besides, it becomes easy to select materials for the function element chip 1 and the mother board 9.

Besides, in this embodiment, the silicon template 42 having the V-shaped grooves 41 thereon is applied. Thereby, it is possible to locate the horizontal coil springs 10 with high degree of accuracy. Therefore, the horizontal coil springs 10 are connected to the function element chip 1 with a high degree of accuracy at a time.

Incidentally, the use of the silicon template 42 shown in this embodiment may be applied to the above-described fourth and fifth embodiment. Besides, by using the silicon template 42, it is possible to connect the horizontal coil springs 10 not only to the function element chip 1 but also to the mother board 9 and the substrate 6.

Next, an explanation will be given of a seventh embodiment of the present invention. FIG. 19 is a side view showing a configuration of a semiconductor device 46h in this embodiment. As shown in FIG. 19, the semiconductor device 46h has a configuration that the function element chip 1 is connected to the mother board 9 through two or more different kinds of coil springs arranged in two or more different direction by means of flip chip bonding. Namely, the chip electrodes 2 are connected to the mother board electrodes 8 electrically and mechanically through the vertical coil springs 4, another kind of vertical coil springs 69, and the horizontal coil springs 10 etc.

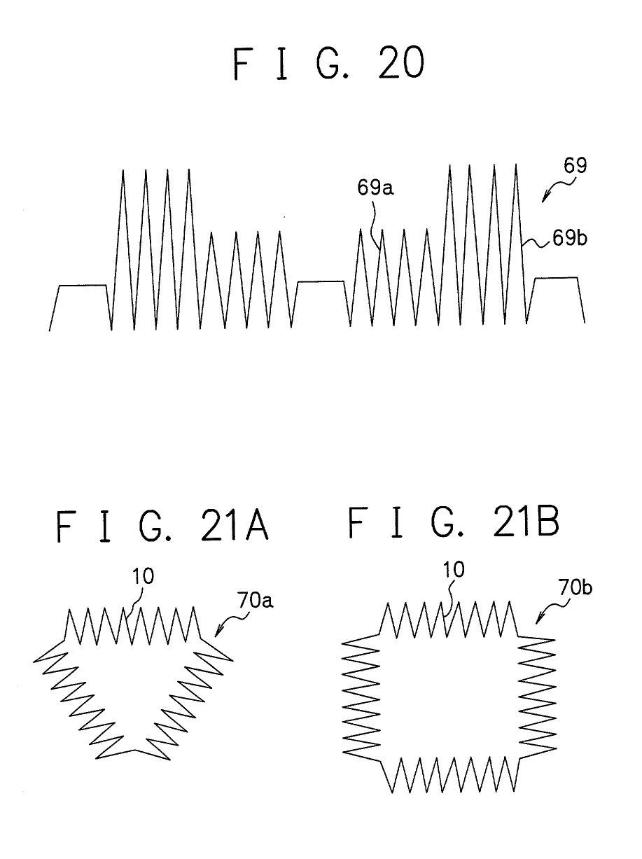

FIG. 20 is a side view showing the shape of the vertical coil spring 69. As shown in FIG. 20, the vertical coil spring 69 has two parts that radii are different, namely, a small radial part 69a and a large radial part 69b. The production method of the semiconductor device 46h in this embodiment is the same as that shown in the sixth embodiment.

In the seventh embodiment, the function element chip 1 is connected to the mother board 9 through two or more different kinds of coil springs arranged in two or more different direction. Thereby, it is possible to effectively relax stress concentration on connecting areas, whose intensity and direction vary according to the positions of connecting areas. Besides, by arranging a plurality of coil springs in various directions, it is possible to relieve stress added to the connecting areas from whole of the semiconductor device in either direction isotropically. In this embodiment, it is also possible to use two or more springs whose elastic constants are different.

FIGS. 21A and 21B are side views showing shapes of coil springs as a first deformed example of the seventh embodiment. A coil spring 70a shown in FIG. 21A has a triangular shape by joining three horizontal coil springs 10. Besides, a coil spring 70b shown in FIG. 21B has a quadrangular shape joining four horizontal coil springs 10. In this deformed embodiment, in the process of manufacturing the semiconductor device 46h shown in FIG. 19, after the coil spring 70a and the coil spring 70b are connected to the chip electrode 2, the coil spring 70a and the coil spring 70b are cut. Thereby, it is possible to connect a plurality of horizontal coil springs 10 each of which has different axial to the chip electrodes 2 at a time. Incidentally, the configuration of the semiconductor device in this deformed embodiment is the same as that of the semiconductor device 46h shown in FIG. 19.

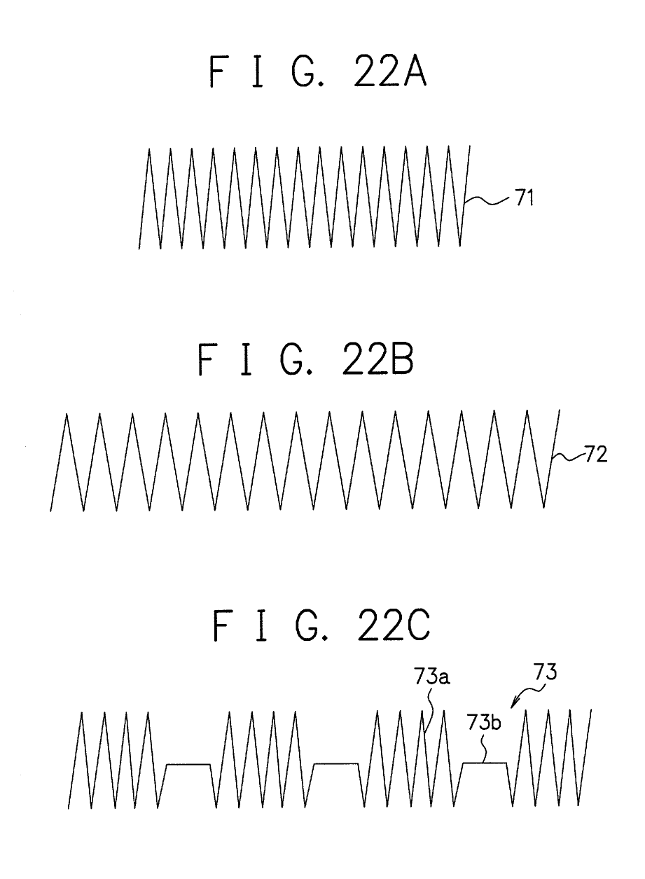

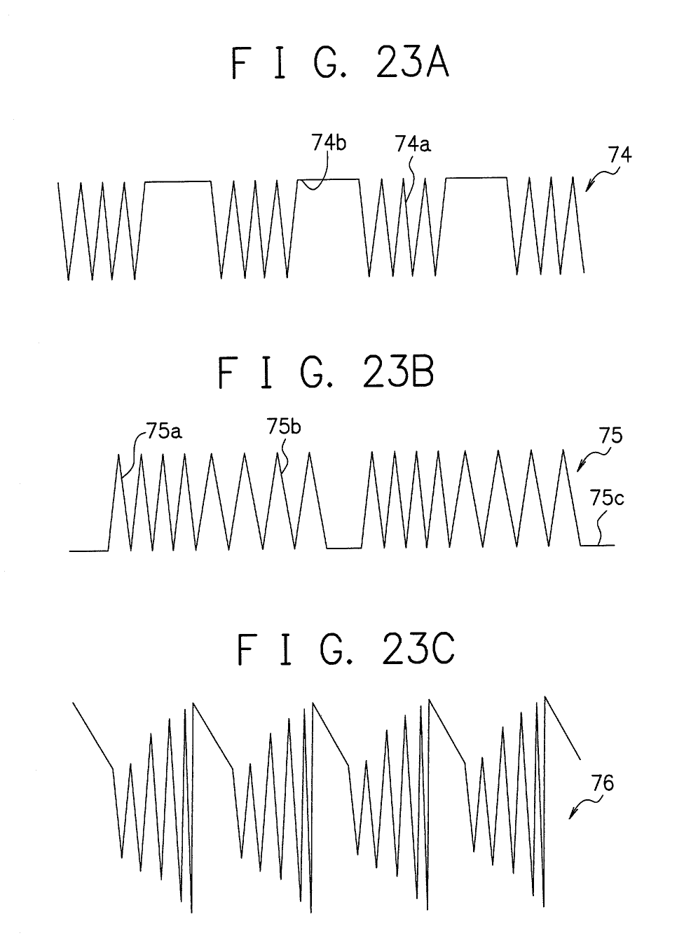

Besides, FIGS. 22A to 22C and FIGS. 23A to 23C are pattern diagrams showing shapes of vertical coil springs as a second deformed example of the seventh embodiment. A pitch of a narrow-pitched coil spring 71 shown in FIG. 22A is narrower than that of the vertical coil spring 4. On the other hand, a pitch of a wide-pitched coil spring 72 shown in FIG. 22B is wider than that of the vertical coil spring 4. An intermittent coil spring 73 shown in FIG. 22C has coil parts 73a and liner parts 73b. An intermittent coil spring 74 shown in FIG. 23A also has coil parts 74A and liner parts 74b. However, the position of the liner parts 74b is different from that of the liner parts 73b viewed from each axial thereof. An intermittent coil spring 75 shown in FIG. 23B has narrow-pitched parts 75a, wide-pitched parts 75b, and liner parts 75c. Concerned with an intermittent coil spring 76 shown in FIG. 23C, the radius changes periodically and continuously. By using these various shapes of coil springs, it is possible to optimize the spring constants of the coil springs, not fixed value, according to the intensity and direction of the stress added to the coil springs.

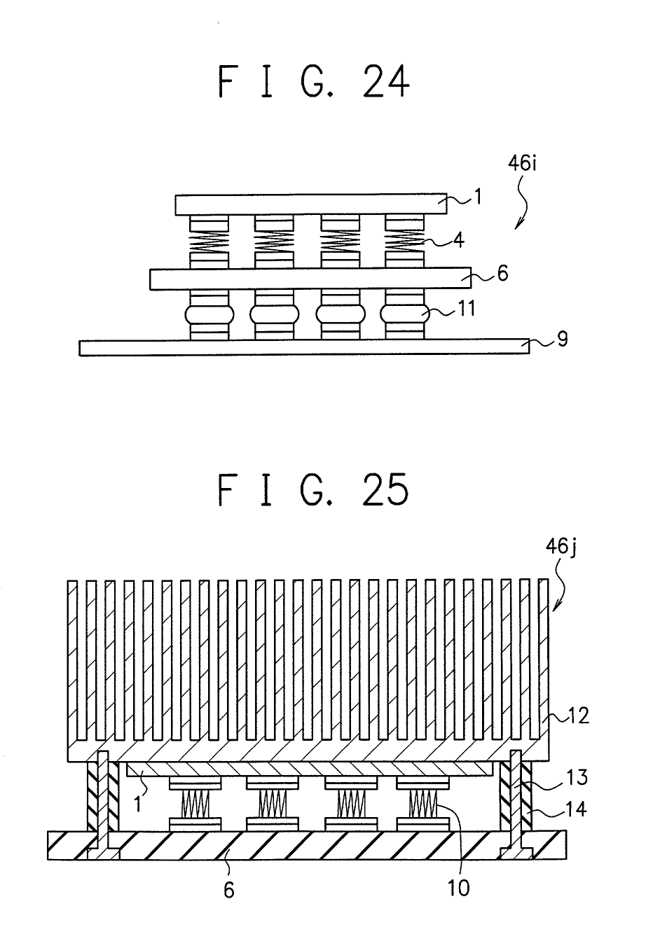

Next, an explanation will be given of an eighth-embodiment of the present invention. FIG. 24 is a side view showing a configuration of a semiconductor device 46i in this embodiment. The configuration of the semiconductor device 46i is the same as that of the semiconductor device 46d shown in FIG. 10 except for conductive bumps 11 substituting for the vertical coil springs 4 between the substrate 6 and the mother board 9.

When the stress caused by the thermal expansion difference between the substrate 6 and the mother board 9 is not too large, the substrate 6 is connected to the mother board 9 through the conductive bumps 11 as shown in the eighth embodiment. Thereby, it is possible to enhance shockproof between the substrate 6 (carrier substrate) and the mother board 9. Therefore, there is obtained a semiconductor device having the flip chip bonding structure wherein shockproof and reliability of connection are high. In addition, it becomes easy to select the configuration, materials etc. for the function element chip 1, substrate 6 and mother board 9. Incidentally, in this embodiment, while there is shown an example of using the vertical coil springs 4 in connecting the function element chip 1 and the substrate 6, it is also possible to use the horizontal coil springs.

Next, an explanation will be given of a ninth embodiment of the present invention. FIG. 25 is a cross sectional view showing a configuration of a semiconductor device 46j in this embodiment. As shown in FIG. 25, the semiconductor device 46j is configured with a heatsink 12 and the semiconductor device 46e shown in FIG. 12. Namely, the horizontal coil springs 10 are placed on the substrate 6. The function element chip 1 is set above the horizontal coil springs 10. The function element chip 1 is connected to the substrate 6 through the horizontal coil springs 10. Then, the heatsink 12 is connected to the backside of the function element chip 1, namely, the side to which the horizontal coil springs 10 are not connected with a jointing material such as a highly thermal conductive resin, solder or Au—Si (not shown). The jointing material is not limited to the material whose thermal expansion coefficient is low or matched to a thermal expansion coefficient of the material for connecting bumps. The jointing material may be the one having an arbitrary characteristic.

Besides, the package structure between the heatsink 12 and the substrate 6 is that a spacer 14 is fixed by a bolt 13 in order to adjust the interval between the heatsink 12 and the substrate 6. Namely, the spacer 14 is placed between the heatsink 12 and the substrate 6 so that the bolt 13 can penetrate the substrate 6 and the spacer 14 in this order and reach to the heatsink 12. Thereby, the substrate 6 and the spacer 14 are joined to the heatsink 12. Further, the space sealed by the heatsink 12, spacer 14 and substrate 6 is filled up with inert gas.

In the ninth embodiment, the heatsink 12 is directly joined to the backside of the function element chip 1. Thereby, even if the function element chip 1 is high power consumption type, the heatsink 12 can give off heat generated by the function element chip 1 effectively. Besides, the horizontal coil springs 10 can absorb stress caused by the thermal expansion difference between the heatsink 12 and the substrate 6, and between the function element chip 1 and the substrate 6. Thereby, with this configuration, there is no need to take account of the stress. Therefore, it becomes unnecessary to subtly adjust the size of the spacer 14 and change the material applied thereto in consideration of the thermal expansion difference. Thereby, it is possible to broaden the options on the structure of the function element chip 1, substrate 6, heatsink 12 etc. In addition, it becomes easier to fit them and thus enabling the simplification of the structure of a semiconductor device with a heatsink. Further, there is obtained a flip-chip type semiconductor device whose packaging cost is low and in which high-power-consumption-type function element is mounted. Incidentally, the vertical coil springs 4 may be used as substitutes for the horizontal coil springs 10.

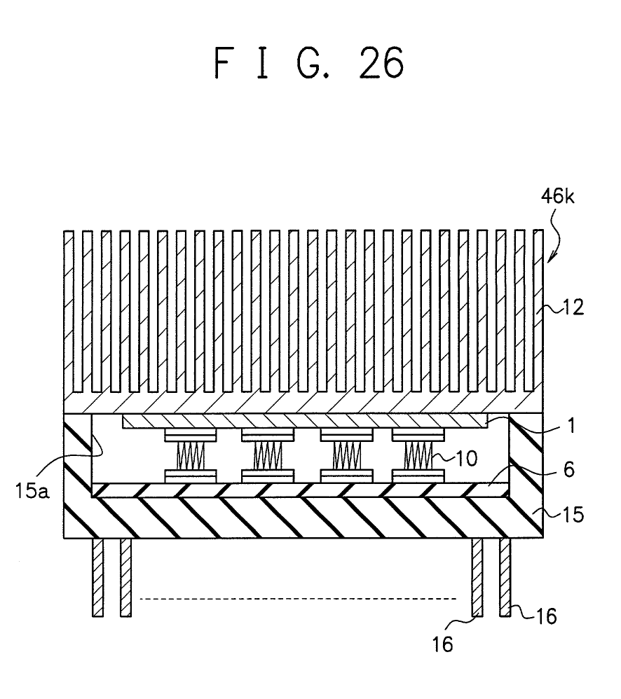

Next, an explanation will be given of a tenth embodiment of the present invention. FIG. 26 is a cross sectional view showing a configuration of a semiconductor device 46k in this embodiment. As shown in FIG. 26, a package 15 having a cavity 15a is set in the semiconductor device 46k. The substrate 6 is mounted at the bottom of the cavity 15a of the package 15. The horizontal coil springs 10 are placed on the substrate 6. The function element chip 1 is set above the horizontal coil springs 10. The function element chip 1 is connected to the substrate 6 through the horizontal coil springs 10. The configuration between the substrate 6 and the function element chip 1 are the same as that of the semiconductor device 46e shown in FIG. 12.

Besides, the heatsink 12 is connected to the backside of the function element chip 1, namely, the side to which the horizontal coil springs 10 are not connected with a jointing material such as a highly thermal conductive resin, solder or Au—Si (not shown). The jointing material is not limited to the material whose thermal expansion coefficient is low or matched to a thermal expansion coefficient of the material for connecting bumps. The jointing material may be the one having an arbitrary characteristic.

Further, the semiconductor device 46k has a package configuration wherein the heatsink 12 is adhered or mechanically joined to the package 15. The package 15 has a plurality of lead pins 16 that are connected to the substrate 6. Besides, the space sealed by the heatsink 12 and the package 15 is filled up with inert gas.

In this embodiment, the package 15 having the cavity 15a is used in the semiconductor device 46k. Thereby, compared to the semiconductor device 46j in the ninth embodiment shown in FIG. 25, a simpler configuration can be achieved. Besides, the horizontal coil springs 10 can absorb stress caused by the thermal expansion difference between the function element chip 1 and the substrate 6, and between the heatsink 12 and the package 15. Thereby, there is no need to take account of the stress. Therefore, it becomes unnecessary to subtly adjust the depth of the cavity 15a of the package 15 and change the material applied thereto in consideration of thermal expansion difference. Thereby, it becomes possible to simplify structure of the function element chip 1, substrate 6, heatsink 12 etc. and fit them easily. Incidentally, the vertical coil springs may be used in this embodiment.

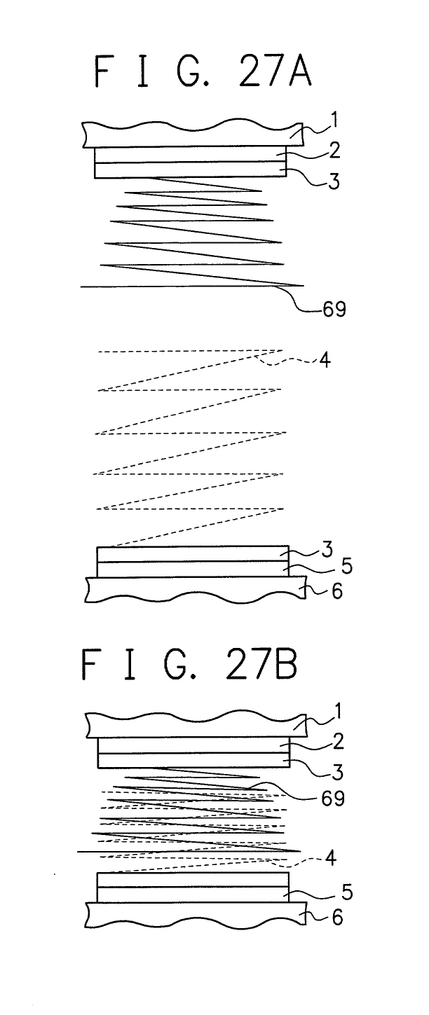

Next, an explanation will be given of an eleventh embodiment of the present invention. FIGS. 27A and 27B are side view showing a configuration and a production method of a semiconductor device in this embodiment, respectively. As shown in FIG. 27B, the function element chip 1 is connected to the substrate 6 through two vertical coil springs, namely, the vertical coil spring 4 and the vertical coil spring 69. The configuration of the semiconductor device in this embodiment is the same as that of the semiconductor device 46a in the first embodiment shown in FIG. 2 except for the vertical coil spring 4 and the vertical coil spring 69.

Next, an explanation will be given of a production method of the semiconductor device in the eleventh embodiment. First, as shown in FIG. 27A, by the same method as that shown in the first embodiment, the vertical coil spring 69 is connected to the chip electrodes 2 formed on the undersurface of the function element chip 1 through the metal layer 3. Besides, in the same way, the vertical coil spring 4 is connected to the topside substrate electrode 5 formed on the top surface of the substrate 6 through the metal layer 3.

Secondly, load is applied to the function element chip 1 and the substrate 6 in the vertical direction so that the vertical coil spring 4 and the vertical coil spring 69 are pressed mutually. Further, scrub or vibration is given in the horizontal direction. Thereby, the vertical coil spring 4 and the vertical coil spring 69 get intertwined mutually.

Consequentially, as shown in FIG. 27B, even if the load added in the vertical direction is removed, the vertical coil spring 4 and the vertical coil spring 69 are electrically connected mutually by the elastic force to restitute.

In this state, an electrical inspection is executed for checking the inside of the function element chip 1 and the connection between the function element chip 1 and the substrate 6. By this inspection, if it is observed that the connection areas are not connected electrically, upward and downward forces are applied thereto so as to detach the function element chip 1 from the substrate 6. Then, the intertwined vertical coil spring 4 and vertical coil spring 69 are separated.

On the contrary, if it is confirmed that the connection areas are connected electrically as a result of the inspection, the function element chip 1 and the substrate 6 are heated up. Then, the vertical coil spring 4 is joined to the vertical coil spring 69. Thereby, there is obtained the semiconductor device in the eleventh embodiment.

According to the production method of this embodiment, when it is observed that the connection areas are not connected electrically as a result of the inspection, it is possible to separate the function element chip 1 from the substrate 6 easily without applying heat to the function element chip 1 and the substrate 6. Thereby, it is possible to prevent damages to the function element chip 1 and the substrate 6. Further, the separated function element chip 1 and the substrate 6 can be reconnected to be used for a semiconductor device again.

Incidentally, in this embodiment, there is shown an example of using the vertical coil spring 4 and the vertical coil spring 69 in order to connect the function element chip 1 and the substrate 6. However, the vertical coil springs used in this embodiment are not limited to these coils. For example, it is possible to arbitrarily select two kinds from the narrow-pitched coil spring 71, wide-pitched coil spring 72, intermittent coil springs 73 to 76 etc. shown in FIGS. 20A and 20B, FIGS. 22A to 22C and FIGS. 23A to 23C.

In addition to the present invention, the sectional shape of the wire forming the coil spring is not limited particularly. For example, the shape may be circular form, elliptical form, square, rectangular, triangle or trapezoid.

As set forth hereinabove, according to this invention, in the semiconductor device having the flip chip bonding structure, the coil springs serve as a means of connecting the function element device to the substrate electrically and mechanically. Thereby, the coil springs can absorb stress concentration caused by the thermal expansion difference between the function element device and the substrate, which was a major problem in the bumps in the conventional semiconductor device. Consequentially, there is no need to consider the configuration, process and materials taking account of the stress concentration to the bumps. Therefore, there is provided a semiconductor device having the flip chip bonding structure wherein the configuration and process are simple, packaging cost is low, and reliability is high. Besides, even if a high-power-consumption-type function element device is applied, the function element device can be connected to the heatsink directly. Thereby, there is obtained a semiconductor device wherein it is possible to realize low thermal resistibility at record level. Further, in the case where a faulty point is found in a connection formation that has a function element device and a substrate as a result of an electrical inspection, the function element device can be mechanically peeled from the substrate or the mother board etc. without heating. Thereby, it is possible to prevent damages to the function element device and the substrate in peeling them. Further, it is possible to connect the once-peeled function element device and the substrate again. Consequentially, it is possible to enhance the reliability of connection of the reconnected function element device and the substrate.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A semiconductor device comprising:
a function element device including a plurality of connection pads;
a substrate including a plurality of connecting electrodes, to which the function element device is connected by means of flip chip bonding; and
a plurality of coil springs set between the connecting pads and the connecting electrodes, and connecting the connecting pads and the connecting electrodes.

2. A semiconductor device comprising:
a function element device including a plurality of connection pads;
a substrate including a plurality of connecting electrodes, to which the function element device is connected by means of flip chip bonding;
a mother board connected to the substrate;
a plurality of mother board connecting electrodes set on a reverse side of a face of the substrate on which the connecting electrodes are set;
a plurality of substrate connecting electrodes set on the mother board, which is connected to the substrate; and
a plurality of coil springs set between the connecting pads and the connecting electrodes, and connecting the connecting pads and the connecting electrodes, and/or set between the mother board connecting electrodes and the substrate connecting electrodes, and connecting the mother board connecting electrodes and the substrate connecting electrodes.

3. The semiconductor device as claimed in claim 1 wherein at least one axial of the coil springs runs in a direction vertical or horizontal to a face substantially opposed to the function element device.

4. The semiconductor device as claimed in claim 2 wherein at least one axial of the coil springs runs in a direction vertical or horizontal to a face substantially opposed to the function element device.

5. The semiconductor device as claimed in claim 1 wherein each of the coil springs is contacted to each of the connecting pads at one contact point.

6. The semiconductor device as claimed in claim 2 wherein each of the coil springs is contacted to each of the connecting pads at one contact point.

7. The semiconductor device as claimed in claim 1 including a plurality of the function element devices.

8. The semiconductor device as claimed in claim 2 including a plurality of the function element devices.

9. The semiconductor device as claimed in claim 1 further including a heatsink fitted to the function element device, and giving off heat generated from the function element device outward.

10. The semiconductor device as claimed in claim 2 further including a heatsink fitted to the function element device, and giving off heat generated from the function element device outward.

11. The semiconductor device as claimed in claim 1 including a package on which the substrate is mounted.

12. The semiconductor device as claimed in claim 2 including a package on which the substrate is mounted.

13. A production method of a semiconductor device, in a wafer on which a plurality of function element devices having connecting pads are set, comprising steps of:
connecting a plurality of coil springs, which are set on each of the connecting pads arranged in a line so that each axial of the coil springs substantially runs in a direction parallel to the arranging direction of the connecting pads, to the connecting pads;
embrocating resist on the wafer, exposing and developing the wafer, forming openings between the connecting pads, and revealing parts of the coil springs in between the connecting pads;
eliminating the revealed parts of the coil springs by etching;
eliminating the resist;
cutting the wafer into each of the function element devices; and
connecting the cut function element device to a plurality of connecting electrodes of a substrate through the coil springs.

14. A production method of a semiconductor device, in a substrate having connecting electrodes, comprising steps of:
connecting a plurality of coil springs, which are set on each of the connecting electrodes arranged in a line so that each axial of the coil springs substantially runs in a direction parallel to the arranging direction of the connecting electrodes, to the connecting electrodes;
embrocating resist on the substrate, exposing and developing the substrate, forming openings between the connecting electrodes, and revealing parts of the coil springs in between the connecting electrodes;
eliminating the revealed parts of the coil springs by etching;
eliminating the resist; and
connecting the connecting electrodes to a plurality of connecting pads of a function element device through the coil springs.

15. A production method of a semiconductor device, in a wafer on which a plurality of function element devices having connecting pads are set, comprising steps of:
connecting a plurality of coil springs, which are set on each of the connecting pads arranged in a line so that each axial of the coil springs substantially runs in a direction parallel to the arranging direction of the connecting pads, to the connecting pads;
cutting each part of the coil springs in between the connecting pads by laser;
cutting the wafer into each of the function element devices; and
connecting the cut function element device to a plurality of connecting electrodes of a substrate through the coil springs.

16. A production method of a semiconductor device, in a substrate having connecting electrodes, comprising steps of:
connecting a plurality of coil springs, which are set on each of the connecting electrodes arranged in a line so that each axial of the coil springs substantially runs in a direction parallel to the arranging direction of the connecting electrodes, to the connecting electrodes;
cutting each part of the coil springs in between the connecting electrodes by laser; and
connecting the connection electrodes to a plurality of connecting pads of a function element device through the coil springs.

17. The production method of the semiconductor device as claimed in claim 13 wherein, when a silicon template is prepared and the wafer is set on the silicon template so that the connecting pads get opposed to the silicon template, a process of setting and connecting the coil springs on the connecting pads comprises steps of:
forming a plurality of V-shaped grooves on a surface of the silicon template so as to be matched with areas to which the coil springs on a surface of the wafer are to be set;
setting the coil springs or a plurality of coil springs cut into a length not greater than a width of each of the connecting pads to the V-shaped grooves;
setting the wafer on a surface of the silicon template so as to contact the connecting pads with the coil springs; and
connecting the coil springs to the connecting pads.

18. The production method of the semiconductor device as claimed in claim 14 wherein, when a silicon template is prepared and the substrate is set on the silicon template so that the connecting electrodes get opposed to the silicon template, a process of setting and connecting the coil springs on the connecting electrodes comprises steps of:
forming a plurality of V-shaped grooves on a surface of the silicon template so as to be matched with areas to which the coil springs on a surface of the substrate are to be set;
setting the coil springs or a plurality of coil springs cut into a length not greater than a width of each of the connecting electrodes to the V-shaped grooves;
setting the substrate on a surface of the silicon template so as to contact the connecting electrodes with the coil springs; and
connecting the coil springs to the connecting electrodes.

19. The production method of the semiconductor device as claimed in claim 15 wherein, when a silicon template is prepared and the wafer is set on the silicon template so that the connecting pads get opposed to the silicon template, a process of setting and connecting the coil springs on the connecting pads comprises steps of:
forming a plurality of V-shaped grooves on a surface of the silicon template so as to be matched with areas to which the coil springs on a surface of the wafer are to be set;
setting the coil springs or a plurality of coil springs cut into a length not greater than a width of each of the connecting pads to the V-shaped grooves;
setting the wafer on a surface of the silicon template so as to contact the connecting pads with the coil springs; and
connecting the coil springs to the connecting pads.

20. The production method of the semiconductor device as claimed in claim 16 wherein, when a silicon template is prepared and the substrate is set on the silicon template so that the connecting electrodes get opposed to the silicon template, a process of setting and connecting the coil springs on the connecting electrodes comprises steps of:
forming a plurality of V-shaped grooves on a surface of the silicon template so as to be matched with areas to which the coil springs on a surface of the substrate are to be set;
setting the coil springs or a plurality of coil springs cut into a length not greater than a width of each of the connecting electrodes to the V-shaped grooves;
setting the substrate on a surface of the silicon template so as to contact the connecting electrodes with the coil springs; and
connecting the coil springs to the connecting electrodes.

21. The production method of the semiconductor device as claimed in claim 13, wherein the connection between the coil springs and the connecting pads are made by one method selected from thermo compression bonding, ultrasonic, scrub or reflow.

22. The production method of the semiconductor device as claimed in claim 14, wherein the connection between the coil springs and the connecting electrodes are made by one method selected from thermo compression bonding, ultrasonic, scrub or reflow.

23. The production method of the semiconductor device as claimed in claim 15, wherein the connection between the coil springs and the connecting pads are made by one method selected from thermo compression bonding, ultrasonic, scrub or reflow.

24. The production method of the semiconductor device as claimed in claim 16, wherein the connection between the coil springs and the connecting electrodes are made by one method selected from thermo compression bonding, ultrasonic, scrub or reflow.

25. A production method of a semiconductor device comprising steps of:
cutting a plurality of coil springs into a prescribed length;
setting the cut coil springs on each of a plurality of connecting pads of a plurality of wafer-type function element devices;
connecting the coil springs to the connecting pads;
dicing the wafer into each of the function element devices;
connecting the connecting pads of the cut function element device to a plurality of connecting electrodes of a substrate through the coil springs, and mounting the function element device on the substrate.

26. A production method of a semiconductor device comprising steps of:
cutting a plurality of coil springs into a prescribed length;
setting the cut coil springs on each of a plurality of connecting electrodes of a substrate;
connecting the coil springs to the connecting electrodes;
connecting the connecting electrodes to a plurality of connecting pads of a function element device through the coil springs, and mounting the function element device on the substrate.

27. A production method of a semiconductor device comprising steps of:
cutting a plurality of coil springs into a prescribed length, and forming a plurality of first and second coil springs;
setting the first coil springs on each of a plurality of connecting pads of a function element device so that each axial of the first coil springs substantially runs in a direction vertical to a face on which the connecting pads are formed, and therewith, setting the second coil springs on each of a plurality of connecting electrodes of a substrate so that each axial of the second coil springs substantially runs in a direction vertical to a face on which the connecting electrodes are formed;
connecting the first coil springs to the connecting pads, and therewith, connecting the second coil springs to the connecting electrodes;
connecting the first coil springs and the second coil springs by entwining them mutually;
executing an electrical inspection to the function element device;
when the function element device is non-defective goods, heating the first and the second coil springs, and joining the first coil springs to the second coil springs; and
when the function element device is defective goods, separating the first coil springs from the second coil springs.

28. The production method of the semiconductor device as claimed in claim 25, wherein each axial of the coil springs substantially runs in a direction vertical to a face on which the connecting pads are set.

29. The production method of the semiconductor device as claimed in claim 26, wherein each axial of the coil springs substantially runs in a direction vertical to a face on which the connecting pads are set.

30. The production method of the semiconductor device as claimed in claim 25, wherein the cutting process comprises steps of:
housing the coil springs into a box through a plurality of hole sections, wherein:
an internal height of the box is larger than an external diameter of each of the coil springs;
at least one side of the box has the plurality of hole sections arranged in a line, whose diameter is larger than the external diameter of each of the coil springs; and
a plurality of slit-shaped openings are set on a side, which is substantially vertical to the side on which the hole sections are set and is substantially parallel to the arranging direction of the hole sections, at prescribed intervals; and
irradiating laser to the coil springs housed within the box through the slit-shaped openings, and cutting the coil springs into a prescribed length.

31. The production method of the semiconductor device as claimed in claim 26, wherein the cutting process comprises steps of:
housing the coil springs into a box through a plurality of hole sections, wherein:
an internal height of the box is larger than an external diameter of each of the coil springs;
at least one side of the box has the plurality of hole sections arranged in a line, whose diameter is larger than the external diameter of each of the coil springs; and
a plurality of slit-shaped openings are set on a side, which is substantially vertical to the side on which the hole sections are set and is substantially parallel to the arranging direction of the hole sections, at prescribed intervals; and
irradiating laser to the coil springs housed within the box through the slit-shaped openings, and cutting the coil springs into a prescribed length.

32. The production method of the semiconductor device as claimed in claim 27, wherein the cutting process comprises steps of:
housing the coil springs into a box through a plurality of hole sections, wherein:
an internal height of the box is larger than an external diameter of each of the coil springs;
at least one side of the box has the plurality of hole sections arranged in a line, whose diameter is larger than the external diameter of each of the coil springs; and
a plurality of slit-shaped openings are set on a side, which is substantially vertical to the side on which the hole sections are set and is substantially parallel to the arranging direction of the hole sections, at prescribed intervals; and
irradiating laser to the coil springs housed within the box through the slit-shaped openings, and cutting the coil springs into a prescribed length.

33. The production method of the semiconductor device as claimed in claim 25, wherein the cutting process comprises steps of:
joining a plurality of tubes which comprise a transparent material transmitting laser and whose internal diameter is larger than an external diameter of each of the coil springs, and inserting the coil springs one by one into the tubes; and
irradiating the laser to the coil springs housed within the tubes so that the laser passes through the side of the tubes from the external thereof, and cutting the coil springs into a prescribed length.

34. The production method of the semiconductor device as claimed in claim 26, wherein the cutting process comprises steps of:
joining a plurality of tubes which comprise a transparent material transmitting laser and whose internal diameter is larger than an external diameter of each of the coil springs, and inserting the coil springs one by one into the tubes; and
irradiating the laser to the coil springs housed within the tubes so that the laser passes through the side of the tubes from the external thereof, and cutting the coil springs into a prescribed length.

35. The production method of the semiconductor device as claimed in claim 27, wherein the cutting process comprises steps of:
joining a plurality of tubes which comprise a transparent material transmitting laser and whose internal diameter is larger than an external diameter of each of the coil springs, and inserting the coil springs one by one into the tubes; and
irradiating the laser to the coil springs housed within the tubes so that the laser passes through the side of the tubes from the external thereof, and cutting the coil springs into a prescribed length.

36. The production method of the semiconductor device as claimed in claim 25 wherein the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward, and exserting the coil springs from the openings set at the head of the guide holes; and
contacting and connecting the coil springs stuck out from the guide holes to the connecting pads or the connecting electrodes.

37. The production method of the semiconductor device as claimed in claim 26 wherein the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward, and exserting the coil springs from the openings set at the head of the guide holes; and
contacting and connecting the coil springs stuck out from the guide holes to the connecting pads or the connecting electrodes.

38. The production method of the semiconductor device as claimed in claim 27 wherein the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward, and exserting the coil springs from the openings set at the head of the guide holes; and
contacting and connecting the coil springs stuck out from the guide holes to the connecting pads or the connecting electrodes.

39. The production method of the semiconductor device as claimed in claim 25 wherein:
each axial of the coil springs substantially runs in a direction vertical to a face on which the connecting pads are set; and
the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward, and exserting the coil springs from the openings set at the head of the guide holes; and
contacting and connecting the coil springs stuck out from the guide holes to the connecting pads or the connecting electrodes.

40. The production method of the semiconductor device as claimed in claim 26 wherein:
each axial of the coil springs substantially runs in a direction vertical to a face on which the connecting pads are set; and
the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward, and exserting the coil springs from the openings set at the head of the guide holes; and
contacting and connecting the coil springs stuck out from the guide holes to the connecting pads or the connecting electrodes.

41. The production method of the semiconductor device as claimed in claim 27 wherein:
each axial of the coil springs substantially runs in a direction vertical to a face on which the connecting pads are set; and
the setting process comprises steps of:
using a coil spring cutting jig having a plurality of guide holes, wherein each of the guide holes has openings above and below thereof, the internal diameter thereof is larger than an external diameter of each of the coil springs, and each of the guide holes is set so as to be matched with a position of each of the connecting pads or the connecting electrodes, and housing the cut coil springs into the guide holes in a line;
intruding a boost-up pin, which can be intruded into the guide holes, from the openings at the bottom of the guide holes, pressing the foot of the housed coil springs, transferring the coil springs upward; and exserting the coil springs from the openings set at the head of the guide holes; and
contacting and connecting the coil springs stuck out from the guide holes to the connecting pads or the connecting electrodes.

42. A coil spring cutting jig for cutting a plurality of coil springs that are to be connected to a function element device or a substrate, comprising a box whose internal height is larger than an external diameter of each of the coil springs, wherein:
a plurality of hole sections whose internal diameter is larger than the external diameter of each of the coil springs are arranged in a line on at least one side of the box, and the coil springs can be inserted and taken out through the hole sections; and
a plurality of slit-shaped openings are set at prescribed intervals on a side substantially vertical to the side on which the hole sections are arranged and substantially parallel to the arranging direction of the hole sections.

43. A coil spring cutting jig for cutting a plurality of coil springs that are to be connected to a function element device or a substrate, comprising:
a plurality of tubes which comprise transparent material transmitting laser, into which the coil springs can be housed, and whose internal diameter is larger than an external diameter of each of the coil springs; and
a tube holder joining and housing the plurality of tubes.

44. A coil spring guiding jig for guiding a plurality of coil springs onto a plurality of connecting pads on a function element device or a plurality of connecting electrodes on a substrate, comprising:
a housing including a plurality of guide holes whose internal diameter is larger than each of the coil springs and each of which has a plurality of openings above and below thereof; and
a boost-up pin that is set at the bottom of the housing and that can be intruded into each of the guide holes, wherein:
each of the guide holes is set so as to be matched with a position of each of the connecting pads or each of the connecting electrodes.
